(19) United States
(12) Patent Application Publication
(10) Pub. No.: US 2026/0031142 A1
(43) Pub. Date: Jan. 29, 2026

(54) MEMORY CONFIGURED TO PROGRAM MEMORY CELLS HAVING DYNAMIC CHANNEL VOLTAGE LEVELS AND METHODS OF THEIR OPERATION

(71) Applicant: MICRON TECHNOLOGY, INC., Boise, ID (US)

(72) Inventors: Jeffrey S. McNeil, Nampa, ID (US); Sheyang Ning, San Jose, CA (US); Lawrence Celso Miranda, San Jose, CA (US); Tomoko Ogura Iwasaki, San Jose, CA (US)

(73) Assignee: MICRON TECHNOLOGY, INC., Boise, ID (US)

(21) Appl. No.: 19/276,256

(22) Filed: Jul. 22, 2025

Related U.S. Application Data
(60) Provisional application No. 63/674,338, filed on Jul. 23, 2024.

(51) Int. Cl. G11C 11/56; G11C 16/04; G11C 16/10; G11C 16/34

(52) U.S. Cl. CPC G11C 11/5628; G11C 11/5671; G11C 16/0483; G11C 16/10; G11C 16/3459

(57) ABSTRACT

Memories might include a controller configured to cause the memory to develop a respective voltage level in a channel of each memory cell of a plurality of memory cells selected for a programming operation, apply a programming voltage level to a selected access line of the programming operation, determine a number of memory cells of the plurality of memory cells passing verify for each data state of a subset of data states, selectively modify values of the respective channel voltage levels in response to at least the determined number of memory cells passing verify for each of the data states of the subset of data states, and perform a subsequent programming operation using the selectively modified values of the channel voltage levels.

### RELATED APPLICATION

This application claims the benefit of U.S. Provisional Application No. 63/674,338, filed on Jul. 23, 2024, hereby incorporated herein in its entirety by reference.

### TECHNICAL FIELD

The present disclosure relates generally to integrated circuits, and, in particular, in one or more embodiments, the present disclosure relates to memories configured to program memory cells having dynamic channel voltage levels and methods of their operation.

### BACKGROUND

Memories (e.g., memory devices) are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically uses a one-transistor memory cell that allows for high memory densities, high reliability, and low power consumption. Changes in threshold voltage (Vt) of the memory cells, through programming (which is often referred to as writing) of charge storage structures (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array is connected together to form an access line, such as a word line. Columns of the array include strings (often termed NAND strings) of memory cells connected together in series between a pair of select gates, e.g., a source select transistor and a drain select transistor. A source select transistor might be connected to a source, while a drain select transistor might be connected to a data line, such as column bit line. Variations using more than one select gate between a string of memory cells and the source, and/or between the string of memory cells and the data line, are known.

In programming memory, memory cells might be programmed as what are often termed single-level cells (SLC). SLC might use a single memory cell to represent one digit (e.g., one bit) of data. For example, in SLC, a Vt of 2.5V or higher might indicate a programmed memory cell (e.g., representing a logical 0) while a Vt of −0.5V or lower might indicate an erased memory cell (e.g., representing a logical 1). Such memory might achieve higher levels of storage capacity by including multi-level cells (MLC), triple-level cells (TLC), quad-level cells (QLC), etc., or combinations thereof in which the memory cell has multiple levels that enable more digits of data to be stored in each memory cell. For example, MLC might be configured to store two digits of data per memory cell represented by four Vt ranges, TLC might be configured to store three digits of data per memory cell represented by eight Vt ranges, QLC might be configured to store four digits of data per memory cell represented by sixteen Vt ranges, and so on.

### BRIEF DESCRIPTION OF THE DRAWINGS

FIG. 1 is a simplified block diagram of a memory in communication with a processor as part of an electronic system, according to an embodiment.

FIGS. 2A-2D are schematics of portions of an array of memory cells as could be used in a memory of the type described with reference to FIG. 1.

FIG. 3 is a conceptual depiction of threshold voltage distributions of a plurality of memory cells as could be used with embodiments.

FIG. 4 depicts a modified schematic of a portion of an array of memory cells as could be used in a memory of the type described with reference to FIG. 1.

FIG. 5 illustrates a timing diagram for a programming pulse of a programming operation in accordance with an embodiment.

FIG. 6 is a timing diagram depicting channel voltage levels and gate-to-body voltage levels that might result from the application of the programming pulse of FIG. 5.

FIG. 7 is a conceptual depiction of interim threshold voltage distributions of a plurality of memory cells that might result from the application of a programming pulse in accordance with an embodiment.

FIGS. 8A-8F are conceptual depictions of threshold voltage distributions of a plurality of memory cells as could be used with embodiments.

FIG. 9 depicts examples of functions that might be used to define the desired change in gate-to-body voltage difference as a function of the number of memory cells passing verify for a data state.

FIG. 10 is a flowchart of a method of operating a memory in accordance with an embodiment.

FIG. 11 is a flowchart of a method of operating a memory in accordance with a further embodiment.

FIGS. 12A-12B are flowcharts of methods of operating a memory in accordance with alternate embodiments.

FIG. 13 is a conceptual depiction of a portion of a trim register as could be used with embodiments.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments might be utilized and structural, logical and electrical changes might be made without departing from the scope of the present disclosure. The following detailed description is, therefore, not to be taken in a limiting sense.

The term “semiconductor” used herein can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps might have been utilized to form regions/junctions in the base semiconductor structure, and the term semiconductor can include the underlying layers containing such regions/junctions.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting by an electrically conductive path unless otherwise apparent from the context.

As used herein, multiple acts being performed concurrently will mean that each of these acts is performed for a respective time period, and each of these respective time periods overlaps, in part or in whole, with each of the remaining respective time periods. In other words, portions of each of those acts are simultaneously performed for at least some period of time.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

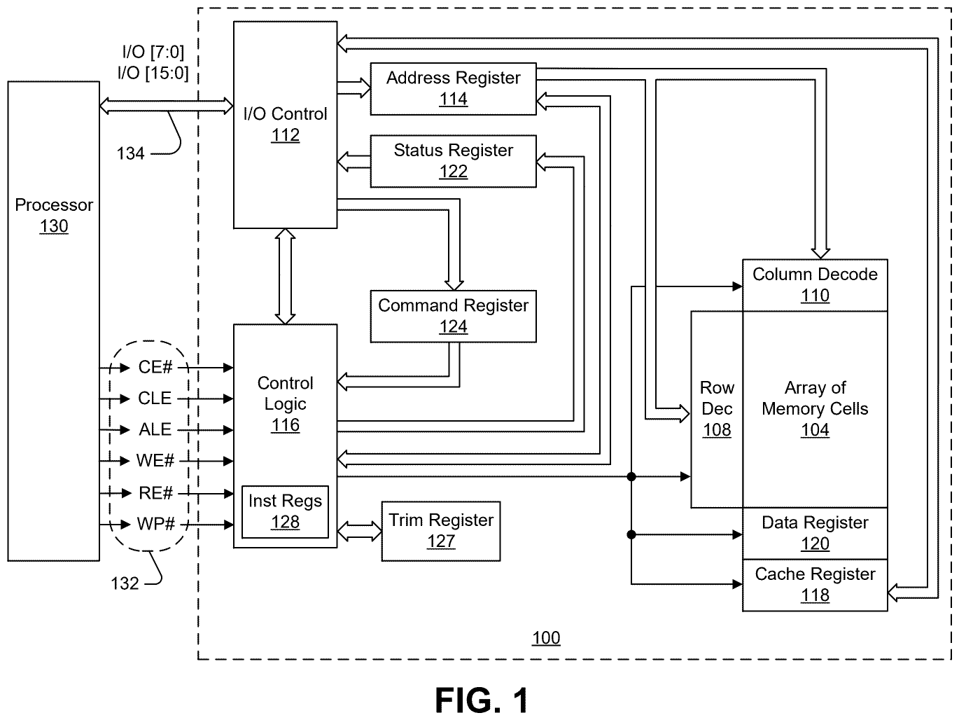

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two different data states.

A row decode circuitry 108 and a column decode circuitry 110 are provided to decode address signals. Address signals are received and decoded to access the array of memory cells 104. Memory device 100 also includes input/output (I/O) control circuitry 112 to manage input of commands, addresses and data to the memory device 100 as well as output of data and status information from the memory device 100. An address register 114 is in communication with I/O control circuitry 112 and row decode circuitry 108 and column decode circuitry 110 to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 104 in response to the commands from the external processor 130 and might generate status information for the external processor 130, i.e., control logic 116 is configured to perform array operations (e.g., sensing operations [which might include read operations and verify operations], programming operations and/or erase operations) on the array of memory cells 104 in accordance with embodiments. The control logic 116 is in communication with row decode circuitry 108 and column decode circuitry 110 to control the row decode circuitry 108 and column decode circuitry 110 in response to the addresses. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 104.

Control logic 116 might also be in communication with a cache register 118. Cache register 118 latches data, either incoming or outgoing, as directed by control logic 116 to temporarily store data while the array of memory cells 104 is busy writing or reading, respectively, other data. During a programming operation (e.g., write operation), data might be passed from the cache register 118 to the data register 120 for transfer to the array of memory cells 104, then new data might be latched in the cache register 118 from the I/O control circuitry 112. During a read operation, data might be passed from the cache register 118 to the I/O control circuitry 112 for output to the external processor 130, then new data might be passed from the data register 120 to the cache register 118. The cache register 118 and/or the data register 120 might form (e.g., might form a portion of) a page buffer of the memory device 100. A data register 120 might further include sense circuits (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

A trim register 127 might be in communication with the control logic 116. The trim register 127 might represent a volatile memory, latches, or other storage location, e.g., volatile or non-volatile. For some embodiments, the trim register 127 might represent a portion of the array of memory cells 104. Trim values might be used by the memory to set values used by an array operation, e.g., voltage levels, timing characteristics, etc., or might be used to selectively activate or deactivate features of the memory. For various embodiments, the trim register 127 might store respective rewritable voltage levels of a programming pulse for programming operations on various groupings of memory cells, e.g., a logical page of memory cells, a physical page of memory cells, a range of logical or physical pages of memory cells, a block of memory cells, multiple blocks of memory cells, etc.

Memory device 100 receives control signals at control logic 116 from processor 130 over a control link 132. The control signals might include a chip enable CE#, a command latch enable CLE, an address latch enable ALE, a write enable WE#, a read enable RE#, and a write protect WP#. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional or alternative circuitry and signals can be provided, and that the memory device 100 of FIG. 1 has been simplified. It should be recognized that the functionality of the various block components described with reference to FIG. 1. might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

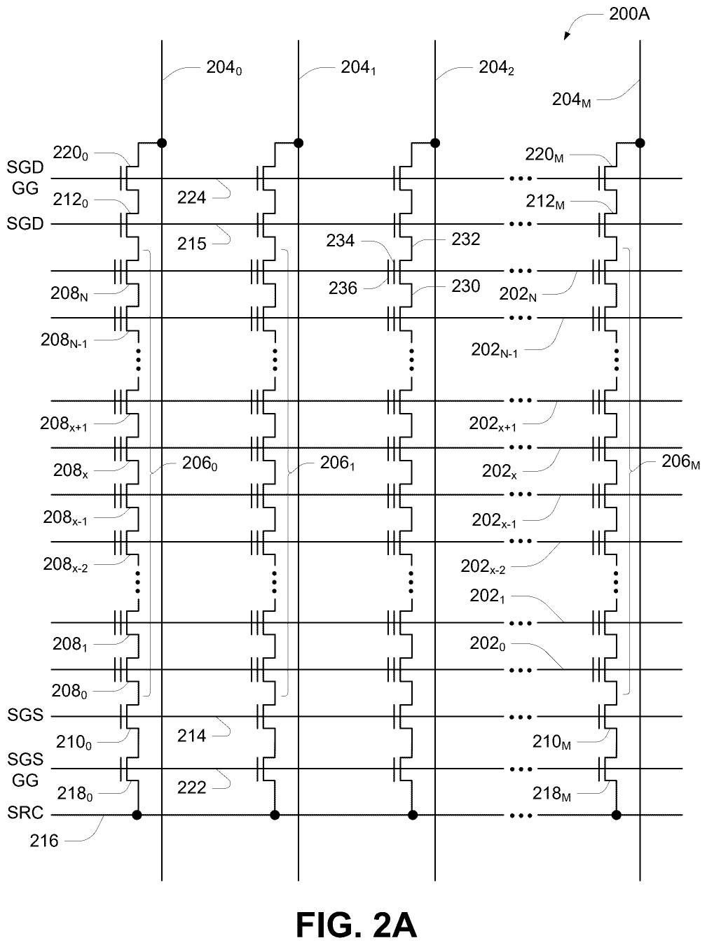

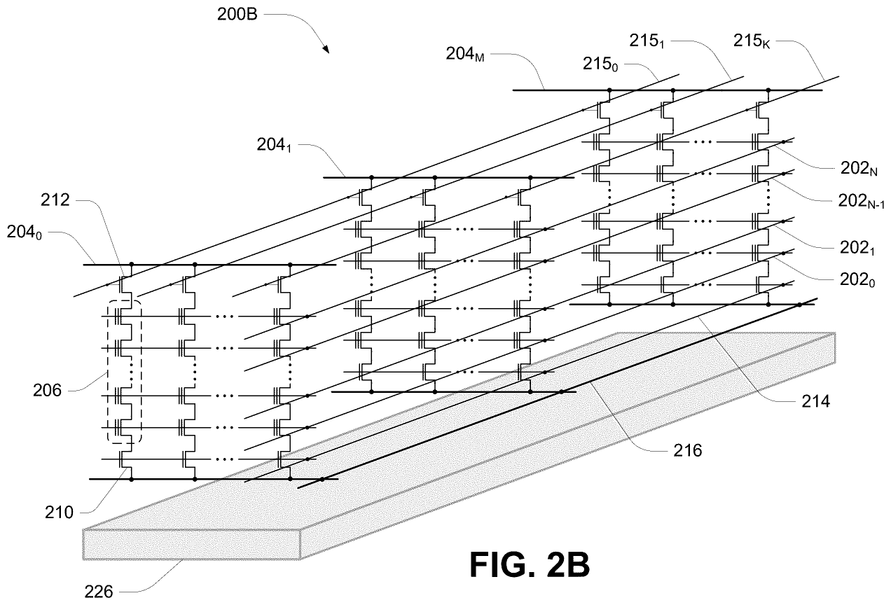

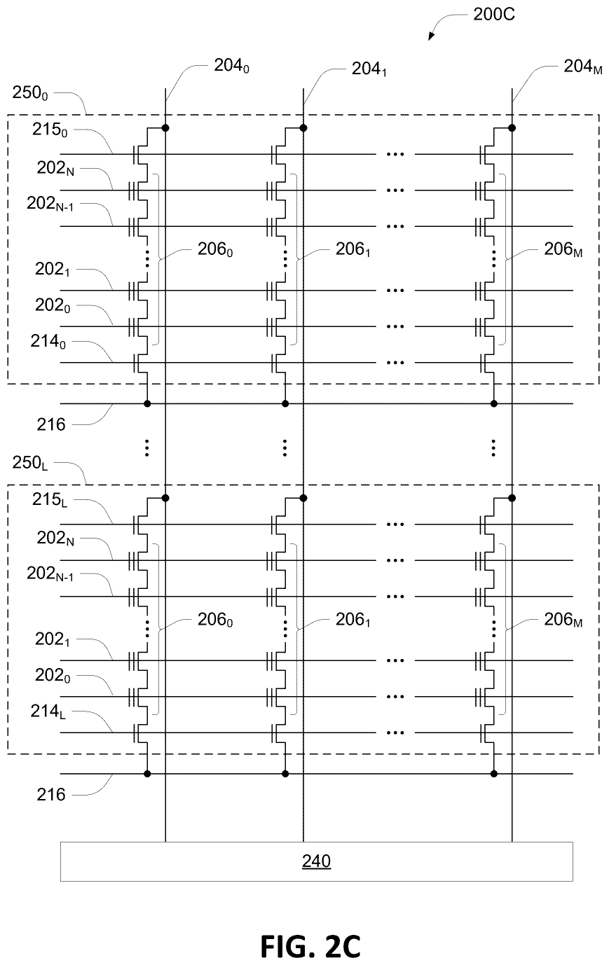

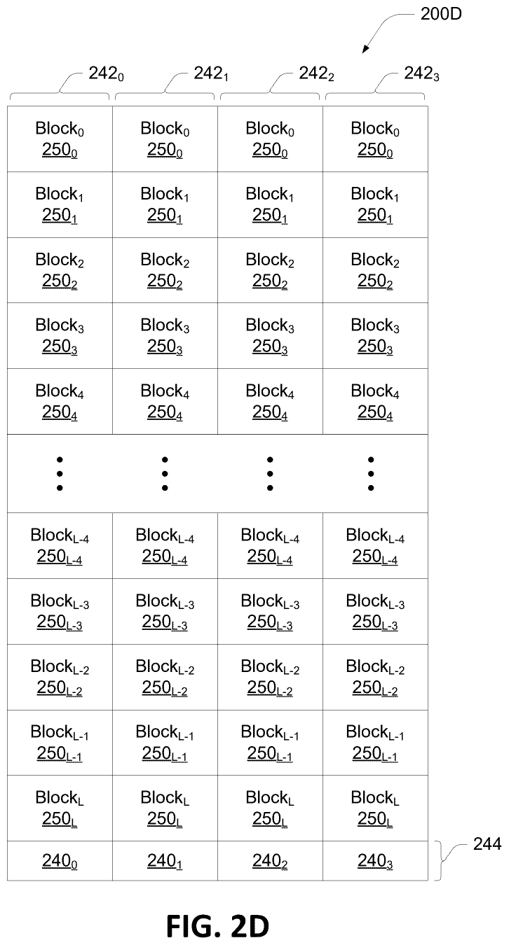

FIG. 2A is a schematic of a portion of an array of memory cells 200A, such as a NAND memory array, as could be used in a memory of the type described with reference to FIG. 1, e.g., as a portion of array of memory cells 104. Memory array 200A includes access lines, such as access lines (e.g., word lines) 202₀ to 202_{N}, and data lines, such as data lines (e.g., bit lines) 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{N}. The memory cells 208 might represent non-volatile memory cells for storage of data. Some of the memory cells 208 might represent dummy memory cells, e.g., memory cells not intended to store user data. Dummy memory cells are typically not accessible to a user of the memory, and are typically incorporated into the NAND string 206 for operational advantages, as are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 212₀ to 212_{M} (e.g., that might be drain select transistors, commonly referred to as select gate drain). Select gates 210₀ to 210_{M} might be commonly connected to a select line 214, such as a source select line (SGS), and select gates 212₀ to 212_{M} might be commonly connected to a select line 215, such as a drain select line (SGD). Although depicted as traditional field-effect transistors, the select gates 210 and 212 might utilize a structure similar to (e.g., the same as) the memory cells 208. The select gates 210 and 212 might represent a plurality of select gates connected in series, with each select gate in series configured to receive a same or independent control signal. A control gate of each select gate 210 might be connected to select line 214. A control gate of each select gate 212 might be connected to select line 215.

The select gates 210 for each NAND string 206 might be connected in series between its memory cells 208 and a GIDL (gate-induced drain leakage) generator gate 218 (e.g., a field-effect transistor), such as one of the GIDL generator (GG) gates 218₀ to 218_{M}. The GG gates 218₀ to 218_{M} might be referred to as source GG gates. The source GG gates 218₀ to 218_{M} might each be connected (e.g., directly connected) to the source 216, and selectively connected to their respective NAND strings 206₀ to 206_{M}. Alternatively, a source select gate 210 and its GG gate 218 might represent a single gate, e.g., connected (e.g., directly connected) to the source 216, and connected (e.g., directly connected) to a respective NAND string 206.

The select gates 212 of each NAND string 206 might be connected in series between its memory cells 208 and a GG gate 220 (e.g., a field-effect transistor), such as one of the GG gates 220₀ to 220_{M}. The GG gates 220₀ to 220_{M} might be referred to as drain GG gates. The drain GG gates 220₀ to 220_{M} might be connected (e.g., directly connected) to their respective data lines 204₀ to 204_{M}, and selectively connected to their respective NAND strings 206₀ to 206_{M}. Alternatively, a drain select gate 212 and its GG gate 220 might represent a single gate, e.g., connected (e.g., directly connected) to a respective data line 204, and connected (e.g., directly connected) to a respective NAND string 206.

GG gates 218₀ to 218 might be commonly connected to a control line 222, such as an SGS_GG control line, and GG gates 220₀ to 220_{M} might be commonly connected to a control line 224, such as an SGD_GG control line. Although depicted as traditional field-effect transistors, the GG gates 218 and 220 might utilize a structure similar to (e.g., the same as) the memory cells 208. The GG gates 218 and 220 might represent a plurality of GG gates connected in series, with each GG gate in series configured to receive a same or independent control signal. In general, the GG gates 218 and 220 might have threshold voltages different than (e.g., lower than) the threshold voltages of the select gates 210 and 212, respectively. Threshold voltages of the source GG gates 218 might be different than (e.g., higher than) threshold voltages of the drain GG gates 220. Threshold voltages of the GG gates 218 and 220 might be of an opposite polarity than, and/or might be lower than, threshold voltages of the select gates 210 and 212, respectively. For example, the select gates 210 and 212 might have positive threshold voltages (e.g., 2V to 4V), while the GG gates 218 and 220 might have negative threshold voltages (e.g., −1V to −4V). The GG gates 218 and 220 might be provided to assist in the generation of GIDL current into a channel of their corresponding NAND string 206 during an erase operation, for example.

A source of each GG gate 218 might be connected to common source 216. The drain of each GG gate 218 might be connected to a select gate 210 of the corresponding NAND string 206. For example, the drain of GG gate 218₀ might be connected to the source of select gate 210₀ of the corresponding NAND string 206₀. Therefore, in cooperation, each select gate 210 and GG gate 218 for a corresponding NAND string 206 might be configured to selectively connect that NAND string 206 to common source 216. A control gate of each GG gate 218 might be connected to control line 222.

The drain of each GG gate 220 might be connected to the data line 204 for the corresponding NAND string 206. For example, the drain of GG gate 220₀ might be connected to the data line 204₀ for the corresponding NAND string 206₀. The source of each GG gate 220 might be connected to a select gate 212 of the corresponding NAND string 206. For example, the source of GG gate 220₀ might be connected to select gate 212₀ of the corresponding NAND string 206₀. Therefore, in cooperation, each select gate 212 and GG gate 220 for a corresponding NAND string 206 might be configured to selectively connect that NAND string 206 to the corresponding data line 204. A control gate of each GG gate 220 might be connected to control line 224.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a data-storage structure 234 (e.g., a floating gate, charge trap, or other structure configured to store charge) that can determine a data state of the memory cell (e.g., through changes in threshold voltage), and a control gate 236, as shown in FIG. 2A. The data-storage structure 234 might include both conductive and dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{N} and selectively connected to even data lines 204 (e.g., data lines 204₀, 204₂, 204₄, etc.) might be one physical page of memory cells 208 (e.g., even memory cells) while memory cells 208 commonly connected to access line 202_{N} and selectively connected to odd data lines 204 (e.g., data lines 204₁, 204₃, 204₅, etc.) might be another physical page of memory cells 208 (e.g., odd memory cells). Although data lines 204₃-204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 202₀-202_{N} (e.g., all NAND strings 206 sharing common access lines 202). Unless expressly distinguished, a reference to a page of memory cells herein refers to the memory cells of a logical page of memory cells.

FIG. 2B is another schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. FIG. 2B provides additional detail of one example of a three-dimensional NAND memory array structure. For clarity, the GG gates and their control lines are not depicted in FIG. 2B.

The three-dimensional NAND memory array 200B might incorporate vertical structures which might include conductively-doped semiconductor pillars, which might be solid or hollow, around which memory cells of NAND strings 206 might be formed. A portion of a pillar might act as a body or channel (e.g., channel region) of the memory cells of NAND strings 206, e.g., a region through which current might flow when a memory cell, e.g., a field-effect transistor, is activated. Each of the NAND strings 206 might be selectively connected to a data line 204₀-204_{M} through a select gate 212 and to a common source 216 through a select gate 210. Multiple NAND strings 206 might be selectively connected to the same data line 204. Subsets of NAND strings 206 can be connected to their respective data lines 204 by biasing the select lines 215₀-215_{K} to selectively activate particular select gates 212 each between a NAND string 206 and a data line 204. The select gates 210 can be activated by biasing the select line 214. Each access line 202 might be connected to multiple rows of memory cells of the memory array 200B. Rows of memory cells that are commonly connected to each other by a particular access line 202 might collectively be referred to as tiers.

The three-dimensional NAND memory array 200B might be formed over peripheral circuitry 226. The peripheral circuitry 226 might represent a variety of circuitry for accessing the memory array 200B. The peripheral circuitry 226 might include complementary circuit elements. For example, the peripheral circuitry 226 might include both n-channel region and p-channel region transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation generally remains as a matter of convenience.

FIG. 2C is a further schematic of a portion of an array of memory cells 200C as could be used in a memory of the type described with reference to FIG. 1, e.g., as a portion of array of memory cells 104. Like numbered elements in FIG. 2C correspond to the description as provided with respect to FIG. 2A. Array of memory cells 200C might include strings of series-connected memory cells (e.g., NAND strings) 206, access (e.g., word) lines 202, data (e.g., bit) lines 204, select lines 214 (e.g., source select lines), select lines 215 (e.g., drain select lines) and common source 216 as depicted in FIG. 2A. A portion of the array of memory cells 200A might be a portion of the array of memory cells 200C, for example. FIG. 2C depicts groupings of NAND strings 206 into blocks of memory cells 250, e.g., blocks of memory cells 250₀-250_{L}. Blocks of memory cells 250 might be groupings of memory cells 208 that might be erased together in a single erase operation, sometimes referred to as erase blocks. Each block of memory cells 250 might represent those NAND strings 206 commonly associated with a single select line 215, e.g., select line 215₀. The source 216 for the block of memory cells 250₀ might be a same source as the source 216 for the block of memory cells 250_{L}. For example, each block of memory cells 250₀-250_{L} might be commonly selectively connected to the source 216. Access lines 202 and select lines 214 and 215 of one block of memory cells 250 might have no direct connection to access lines 202 and select lines 214 and 215, respectively, of any other block of memory cells of the blocks of memory cells 250₀-250_{L}.

The data lines 204₀-204_{M} might be connected (e.g., selectively connected) to a buffer portion 240, which might be a portion of a data buffer of the memory. The buffer portion 240 might correspond to a memory plane (e.g., the set of blocks of memory cells 250₀-250_{L}). The buffer portion 240 might include sense circuits (not shown in FIG. 2C) for sensing data values indicated on respective data lines 204.

FIG. 2D is a block schematic of a portion of an array of memory cells as could be used in a memory of the type described with reference to FIG. 1. The array of memory cells 200D is depicted to have four memory planes 242 (e.g., memory planes 242₀-242₃), each in communication with a respective buffer portion 240 (e.g., buffer portions 240₀-240₃), which might collectively form a data buffer (e.g., page buffer) 244. While four memory planes 242 are depicted, other numbers of memory planes 242 might be commonly in communication with a data buffer 244. Each memory plane 242 is depicted to include L+1 blocks of memory cells 250 (e.g., blocks of memory cells 250₀-250_{L}).

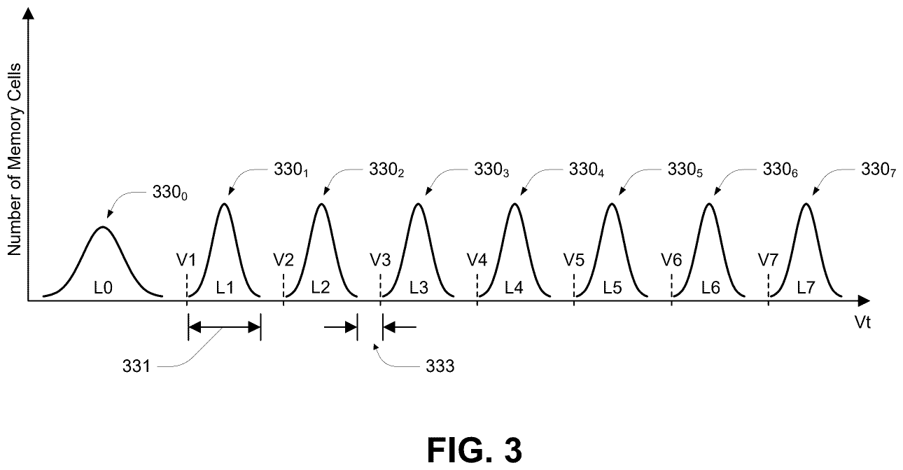

FIG. 3 is a conceptual depiction of threshold voltage distributions of a plurality of memory cells as could be used with embodiments. FIG. 3 illustrates an example of threshold voltage distributions and their threshold voltage ranges for a population of eight-level (e.g., three-bit) memory cells, often referred to as TLC memory cells. For example, such a memory cell might be programmed to a threshold voltage (Vt) that falls within one of eight different threshold voltage distributions 330₀-330₇, each being used to represent a data state corresponding to a bit pattern of three bits. The threshold voltage distribution 330₀ typically has a greater width than the remaining threshold voltage distributions 330₁-330₇ as memory cells are generally all placed in the data state corresponding to the threshold voltage distribution 330₀, then subsets of those memory cells are subsequently programmed to have threshold voltages in one of the threshold voltage distributions 330₁-330₇. As programming operations are often more incrementally controlled than erase operations, these threshold voltage distributions 330₁-330₇ might tend to have tighter distributions.

The threshold voltage distributions 330₀, 330₁, 330₂, 330₃, 330₄, 330₅, 330₆ and 330₇ might each represent a respective data state, e.g., L0, L1, L2, L3, L4, L5, L6 and L7, respectively. The threshold voltage distributions 330₁-330₇ might each have a width 331, e.g., a voltage difference between a highest voltage level and a lowest voltage level of the corresponding threshold voltage distribution 330. In addition, a dead space or margin 333 is typically maintained between adjacent threshold voltage distributions 330₁-330₇ during programming in order to mitigate subsequent overlapping of the threshold voltage distributions over time. The width 331 of any one threshold voltage distribution 330₁-330₇ might be the same or different than the width 331 of any other threshold voltage distribution 330₁-330₇. Similarly, the margin 333 between any pair of adjacent threshold voltage distributions 330 might be the same or different than the margin 333 between any remaining pair of adjacent threshold voltage distributions 330. The sum of the margins 333 for each of the threshold voltage distributions 330 might be referred to as a read window budget (RWB).

As depicted in FIG. 3, if the threshold voltage of a memory cell is within the first (e.g., lowest) of the eight threshold voltage distributions 330₀, the memory cell in this case might be storing a data state L0 having a data value of logical 111 and is typically referred to as the erased state of the memory cell. If the threshold voltage is within the second of the eight threshold voltage distributions 330₁, the memory cell in this case might be storing a data state L1 having a data value of logical 011. If the threshold voltage is within the third of the eight threshold voltage distributions 330₂, the memory cell in this case might be storing a data state L2 having a data value of logical 001, and so on. Table 1 provides one possible correspondence between the data states and their corresponding logical data values. Other assignments of data states to logical data values are known.

TABLE 1

| | Logical |
|---|---|
| Data | Data |
| State | Value |
| L0 | 111 |
| L1 | 011 |
| L2 | 001 |
| L3 | 101 |
| L4 | 100 |
| L5 | 000 |
| L6 | 010 |
| L7 | 110 |

Program-verify voltage levels, or simply verify voltage levels, V1-V7 might be used to determine whether a memory cell being programmed has reached a particular threshold voltage distribution 330₁-330₇, respectively. For example, a memory cell being programmed to the data state L1 might be enabled for programming for one or more programming pulses (e.g., one or more programming pulses of increasing programming voltage levels) of a programming operation until it can no longer be activated in response to a gate-source voltage equal to the verify voltage level V1, a memory cell being programmed to the data state L2 might be enabled for programming for one or more programming pulses of the programming operation until it can no longer be activated in response to a gate-source voltage equal to the verify voltage level V2, a memory cell being programmed to the data state L3 might be enabled for programming for one or more programming pulses of the programming operation until it can no longer be activated in response to a gate-source voltage equal to the verify voltage level V3, and so on.

Programming in memories is typically accomplished by applying one or more programming pulses, separated by verify pulses, to program each memory cell of a selected group of memory cells to a respective desired data state (which might be an interim or final data state). With such a technique, the programming pulses are applied to access lines, such as those typically referred to as word lines, for selected memory cells. After each programming pulse, a verify pulse of one or more verify voltage levels is typically used to verify the programming of the selected memory cells. Programming typically uses many programming pulses using an incremental step pulse programming (ISPP) technique, where each programming pulse generally moves the memory cell threshold voltage by some amount, and each subsequent programming pulse has a higher programming voltage level than its preceding programming pulse.

The programming pulses might be applied to a selected access line (e.g., word line) and thus to the control gates of the row of memory cells connected to the selected access line (e.g., having their control gates connected to the selected access line). Typical programming pulses might start at or near 13V and tend to increase in magnitude for each subsequent programming pulse application. While the programming voltage level (e.g., a highest voltage level of the programming pulse) is applied to the selected access line, an enable voltage, such as a reference potential (e.g., Vss, ground, or 0V), might be applied to the channels of memory cells selected for programming that have not yet reached a desired data state, i.e., those memory cells for which the programming operation is intended to shift their data state to some higher level. This might result in a charge transfer from the channel to the data storage structures of these selected memory cells. For example, floating gates are typically charged through direct injection or Fowler-Nordheim tunneling of electrons from the channel to the floating gate, resulting in an increased threshold voltage in a programmed state.

An inhibit voltage level (e.g., Vcc) is typically applied to data lines which are selectively connected to a NAND string containing a memory cell that is connected to the selected access line and is not selected for, or is no longer selected for, programming. In addition to data lines selectively connected to memory cells already at their desired data state, these unselected data lines might further include data lines that are not addressed by the programming operation. For example, a logical page of data might correspond to memory cells connected to a particular access line and selectively connected to some particular subset of the data lines (e.g., every other data line), such that the remaining subset of data lines would be unselected for the programming operation and thus inhibited.

Between the application of one or more programming pulses, a verify phase of the programming operation is typically performed to check each selected memory cell to determine whether it has reached its desired data state. If a selected memory cell has reached its desired data state, it might be inhibited from further programming if there remain other selected memory cells still requiring additional programming pulses to reach their desired data states. Following a verify phase, an additional programming pulse might be applied if there are memory cells that have not completed programming. This process of applying a programming pulse followed by verification (e.g., a programming phase and a verify, or sensing, phase of a programming operation) typically continues until all the selected memory cells have reached their desired data states. If a particular number of programming pulses (e.g., maximum number) have been applied, or a particular voltage level of a programming pulse (e.g., maximum voltage level) has been reached, and one or more selected memory cells still have not completed programming, those memory cells might be marked as defective, for example.

Various embodiments seek to facilitate improvements in boosted channel programming by incorporating dynamic modification of channel voltage levels in response to numbers of memory cells of a plurality of data states passing verify in response to a programming pulse, e.g., through modification of voltage levels to be used for a subsequent programming pulse. The modified channel voltage levels could be used in subsequent programming operations to facilitate improvements in the numbers of memory cells passing verify in response to a programming pulse (e.g., an initial programming pulse) and/or improvements in the widths of threshold voltage distributions for the plurality of data states.

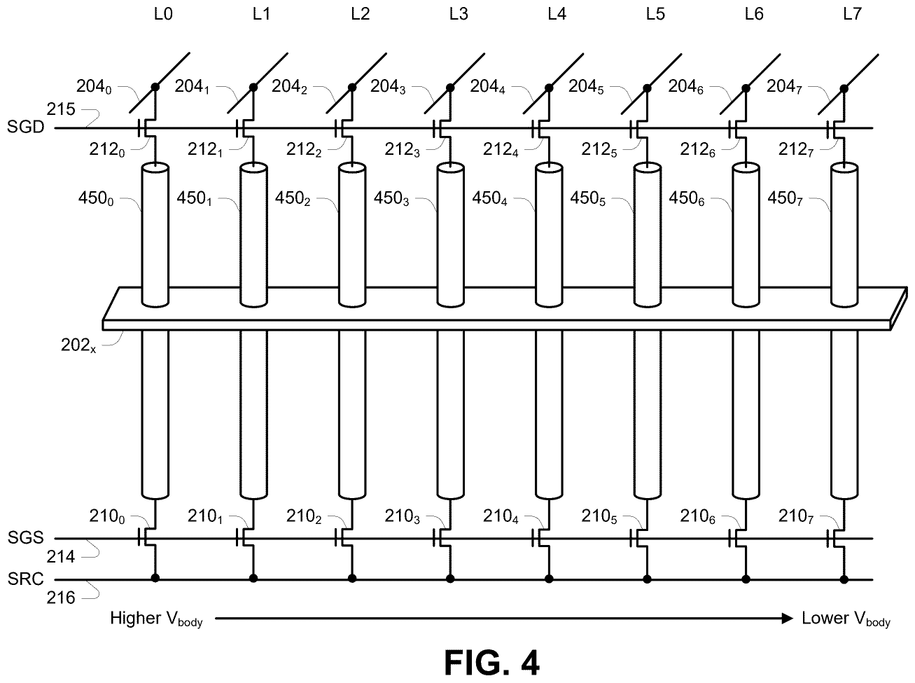

In discussing boosted channel programming, consider the example of a TLC memory having eight memory cells, each having a desired data state corresponding to a respective one of the possible data states of TLC memory cells, e.g., data states L0-L7. FIG. 4 depicts a modified schematic of a portion of an array of memory cells as could be used in a memory of the type described with reference to FIG. 1. Like numbered elements in FIG. 4 correspond to the description as provided with respect to FIG. 2A. For clarity, only a selected access line 202ₓ is depicted in FIG. 4. In addition, GIDL generator gates and individual memory cells are similarly not depicted.

In FIG. 4, the selected access line 202ₓ is depicted to intersect with the pillars 450, e.g., pillars 450₀-450₇. Each pillar 450 might be a conductively-doped semiconductor pillar, for example, whether hollow or solid. A portion of each pillar 450 might act as a channel of memory cells formed at its intersection with each access line. In the example of FIG. 4, a memory cell formed at an intersection of the pillar 450₀ and the selected access line 202ₓ might have a desired data state of L0 for a programming operation, a memory cell formed at an intersection of the pillar 450₁ and the selected access line 202ₓ might have a desired data state of LI for the programming operation, a memory cell formed at an intersection of the pillar 450₂ and the selected access line 202ₓ might have a desired data state of L2 for the programming operation, a memory cell formed at an intersection of the pillar 4503 and the selected access line 202ₓ might have a desired data state of L3 for the programming operation, a memory cell formed at an intersection of the pillar 4504 and the selected access line 202ₓ might have a desired data state of L4 for the programming operation, a memory cell formed at an intersection of the pillar 450₅ and the selected access line 202ₓ might have a desired data state of L5 for the programming operation, a memory cell formed at an intersection of the pillar 450₆ and the selected access line 202ₓ might have a desired data state of L6 for the programming operation, and a memory cell formed at an intersection of the pillar 450₇ and the selected access line 202ₓ might have a desired data state of L7 for the programming operation.

Boosted channel programming traditionally seeks to develop differing voltage levels in the channel of selected memory cells of differing desired data states prior to applying the programming voltage level of a programming pulse. Continuing with the example, the voltage level of the channels of each selected memory cell, e.g., V_{ch}, might be the highest for a selected memory cell having the lowest desired data state, e.g., L0 (or having previously been determined to pass verification), and might be the lowest for a selected memory cell having the highest desired data state, e.g., L7. This leads to higher gate-to-body voltage differences for memory cells having higher data states than memory cells having lower data states, such that memory cells having higher data states might be expected to have a larger threshold voltage change (e.g., larger charge accumulation) than memory cells having lower data states in response to a same control gate voltage level.

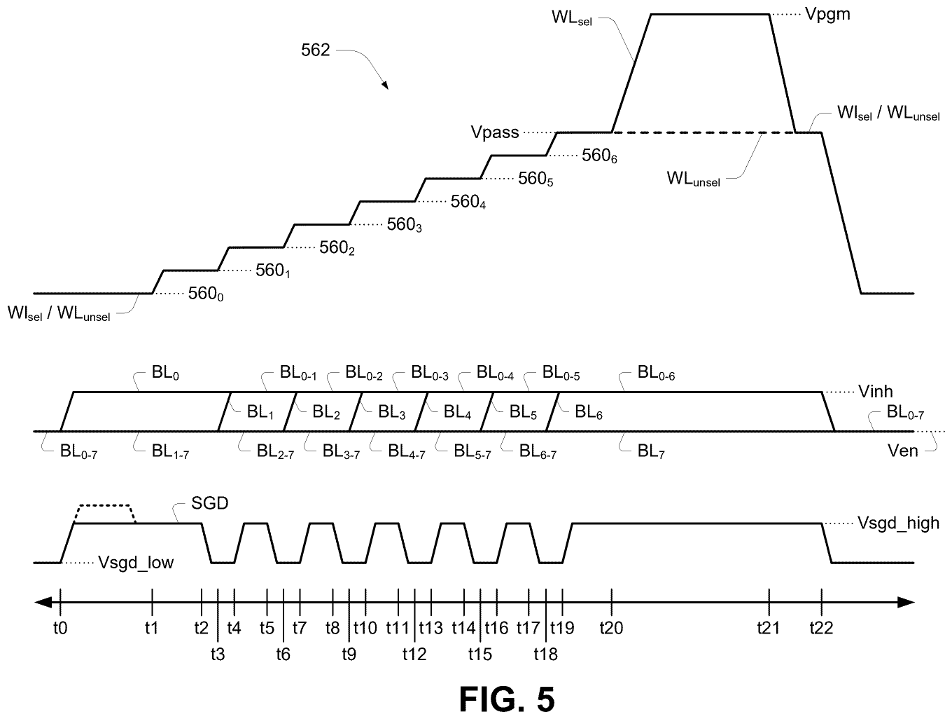

FIG. 5 illustrates a timing diagram for a programming pulse 562 of a programming operation in accordance with an embodiment. The example of FIG. 5 describes a programming operation for TLC memory cells, but the concepts can be applied to the programming of higher or lower numbers of digits per memory cell. The process will be described with reference to an array architecture of the types depicted in FIGS. 2A and 4, and with reference to data states such as depicted in FIG. 3. The process will generally refer to a selected access line (e.g., selected word line) that is connected to one or more memory cells selected for programming and an unselected access line (e.g., unselected word line) that is connected to one or more memory cells not selected for programming, e.g., not connected to any memory cell selected for programming. Voltage levels applied to the selected access line (e.g., access line 202ₓ of FIGS. 2A or 4) are represented by the trace WLₛₑₗ while voltage levels applied to the unselected access line (e.g., any access line other than access line 202ₓ of FIGS. 2A or 4) are represented by trace WLᵤₙₛₑₗ. Although only one unselected access line is discussed with reference to FIG. 5, one or more additional (e.g., including up to all) unselected access lines of a NAND string 206 might receive the same voltage levels, although other schemes might also be used.

The process of FIG. 5 might also generally refer to selected data lines 204 (e.g., selected bit lines) each selectively connected to a memory cell selected for programming to one of the L1-L7 data states, and unselected data lines 204 (e.g., unselected bit lines) that are selectively connected to memory cells connected to the selected access line that are to remain in the L0 data state. Voltage levels applied to the selected data lines 204 for data states L1-L7 (e.g., data lines 204₁-204₇ of FIG. 4) are represented by traces BL₁-BL₇, respectively, while voltage levels applied to the unselected data lines 204 for data state L0 (e.g., data line 204₀ of FIG. 4) are represented by trace BL₀. The voltage levels applied to the select gate drain 215, and thus to the drain select gates 212, are represented by trace SGD. The voltage levels applied to the select gate source 214 (not depicted in FIG. 5) might be configured to deactivate the corresponding source select gates 210, throughout the relevant time periods of FIG. 5.

Prior to time t0, the voltage level applied to WLₛₑₗ and WLᵤₙₛₑₗ might be at a voltage level 560₀, which might be the reference potential, although other voltage levels might be used to attain desired levels of channel boosting during the programming pulse 562. The voltage level applied to BL0-BL7 (e.g., data lines 204₀-204₇, respectively, of FIG. 4) might be at an enable voltage level Ven, which might be the reference potential, although other voltage levels might be used to attain desired activation or deactivation of the drain select gates in response to the voltage levels applied to SGD. And the voltage level applied to SGD might be at a voltage level Vsgd_low, which might be the reference potential, although other voltage levels might be used to attain deactivation of the drain select gates.

At time to, the voltage level applied to the BL₀ might be increased to an inhibit voltage level Vinh (e.g., Vcc) while the voltage level applied to BL₁-BL₇ remains at the enable voltage level Ven. In conjunction, the voltage level applied to SGD might be increased to a voltage level Vsgd_high. This might electrically float the respective channels of the memory cells having the L0 desired data state, and apply the enable voltage level Ven to the respective channels of the memory cells having any of the L1-L7 data states.

As depicted in dashed line, the voltage level applied to SGD might alternatively be increased to a voltage level higher than Vsgd_high that might be sufficient to activate the corresponding select gates to pass the voltage level of BL₀ to the channels of the corresponding NAND strings connected to the selected access line before being decreased to Vsgd_high before time t1. The voltage level Vsgd_high might be a voltage level sufficient to activate select gates 212 connected to data lines 204 to which the enable voltage level Ven is applied and to deactivate select gates 212 connected to data lines 204 to which the inhibit voltage level Vinh is applicd.

At time t1, the voltage level applied to WLₛₑₗ and WLᵤₙₛₑₗ might be increased to a voltage level 560₁, boosting the channel voltage level (Vch) of the memory cells connected to the selected access line that are to remain at the L0 data state, e.g., through capacitive coupling. At time t2 (e.g., after WLₛₑₗ and WLᵤₙₛₑₗ have reached the voltage level 560₁), the voltage level applied to SGD might be decreased to the voltage level Vsgd_low. This might serve to lock the respective channel voltage levels for each data state L0-L7 (e.g., the channel voltage levels of the pillars 450₀-450₇, respectively, of FIG. 4) before any changes are made to data line voltage levels by isolating each NAND string from its corresponding data line and electrically floating their respective channels. Alternatively, the voltage level applied to SGD might remain at the voltage level Vsgd_high at time t2.

At time t3, the voltage level applied to WLₛₑₗ and WLᵤₙₛₑₗ might be increased to a voltage level 560₂, further boosting the channel voltage level of the memory cells connected to the selected access line that are to remain at the L0 data state. If SGD is decreased to Vsgd_low at time t2, the voltage level applied to BL₁ might be increased to the inhibit voltage level Vinh between times t2 and t4, and might be increased concurrently with the increase of the voltage level applied to Wlₛₑₗ and WLᵤₙₛₑₗ at time t3. If the voltage level applied to SGD is alternatively maintained at Vsgd_high at time t2, the voltage level applied to BL₁ might be increased to the inhibit voltage level Vinh prior to time t3 (e.g., after time tl and prior to time t3) in order to isolate the NAND strings corresponding to the L1 data state from their corresponding data lines prior to increasing the voltage level applied to Wlₛₑₗ and WLᵤₙₛₑₗ at time t3. In either case, the increase of WLₛₑₗ and WLᵤₙₛₑₗ to the voltage level 560₂ might boost the channel voltage level of the memory cells connected to the selected access line that have L1 desired data state. At time t4, SGD might be returned to the voltage level Vsgd_high. While channel voltage levels of memory cells connected to the selected access line that have the L2-L7 data states might be boosted at time t3 if SGD is at the voltage level Vsgd_low, these channels might be expected to discharge back to the enable voltage level Ven at time t4 upon being reconnected to their respective data lines.

At time t5 (e.g., after WLₛₑₗ and WLᵤₙₛₑₗ have reached the voltage level 560₂), the voltage level applied to SGD might be decreased to the voltage level Vsgd_low. This might serve to lock the respective channel voltage levels for each data state L0-L7 (e.g., the channel voltage levels of the pillars 450₀-450₇, respectively) before any changes are made to data line voltage levels by isolating each NAND string from its corresponding data line and electrically floating their respective channels. Alternatively, the voltage level applied to SGD might remain at the voltage level Vsgd_high at time t5.

At time t6, the voltage level applied to WLₛₑₗ and WLᵤₙₛₑₗ might be increased to a voltage level 560₃, further boosting the channel voltage level of the memory cells connected to the selected access line that are to remain at the L0 and L1 data states. If SGD is decreased to Vsgd_low at time t5, the voltage level applied to BL₂ might be increased to the inhibit voltage level Vinh between times t5 and t7, and might be increased concurrently with the increase of the voltage level applied to Wlₛₑₗ and WLᵤₙₛₑₗ at time t6. If the voltage level applied to SGD is alternatively maintained at Vsgd_high at time t5, the voltage level applied to BL₂ might be increased to the inhibit voltage level Vinh prior to time t6 (e.g., after time t4 and prior to time t6) in order to isolate the NAND strings corresponding to the L2 data state from their corresponding data lines prior to increasing the voltage level applied to Wlₛₑₗ and WLᵤₙₛₑₗ at time t6. In either case, the increase of WLₛₑₗ and WLᵤₙₛₑₗ to the voltage level 560₃ might boost the channel voltage level of the memory cells connected to the selected access line that have the L2 desired data state. At time t7, SGD might be returned to the voltage level Vsgd_high. While channel voltage levels of memory cells connected to the selected access line that have the L3-L7 data states might be boosted at time t6 if SGD is at the voltage level Vsgd_low, these channels might be expected to discharge back to the enable voltage level Ven at time t7 upon being reconnected to their respective data lines.

At time t8 (e.g., after WLₛₑₗ and WLᵤₙₛₑₗ have reached the voltage level 560₃), the voltage level applied to SGD might be decreased to the voltage level Vsgd_low. This might serve to lock the respective channel voltage levels for each data state L0-L7 (e.g., the channel voltage levels of the pillars 450₀-450₇, respectively) before any changes are made to data line voltage levels by isolating each NAND string from its corresponding data line and electrically floating their respective channels. Alternatively, the voltage level applied to SGD might remain at the voltage level Vsgd_high at time t8.

At time t9, the voltage level applied to WLₛₑₗ and WLᵤₙₛₑₗ might be increased to a voltage level 560₄, further boosting the channel voltage level of the memory cells connected to the selected access line that are to remain at the L0-L2 data states. If SGD is decreased to Vsgd_low at time t8, the voltage level applied to BL3 might be increased to the inhibit voltage level Vinh between times t8 and t10, and might be increased concurrently with the increase of the voltage level applied to Wlₛₑₗ and WLᵤₙₛₑₗ at time t9. If the voltage level applied to SGD is alternatively maintained at Vsgd_high at time t8, the voltage level applied to BL3 might be increased to the inhibit voltage level Vinh prior to time t9 (e.g., after time t7 and prior to time t9) in order to isolate the NAND strings corresponding to the L3 data state from their corresponding data lines prior to increasing the voltage level applied to Wlₛₑₗ and WLᵤₙₛₑₗ at time t9. In either case, the increase of WLₛₑₗ and WLᵤₙₛₑₗ to the voltage level 560₄ might boost the channel voltage level of the memory cells connected to the selected access line that have the L3 desired data state. At time t10, SGD might be returned to the voltage level Vsgd_high. While channel voltage levels of memory cells connected to the selected access line that have the L4-L7 data states might be boosted at time t9 if SGD is at the voltage level Vsgd_low, these channels might be expected to discharge back to the enable voltage level Ven at time t10 upon being reconnected to their respective data lines.

At time t11 (e.g., after WLₛₑₗ and WLᵤₙₛₑₗ have reached the voltage level 560₄), the voltage level applied to SGD might be decreased to the voltage level Vsgd_low. This might serve to lock the respective channel voltage levels for each data state L0-L7 (e.g., the channel voltage levels of the pillars 450₀-450₇, respectively) before any changes are made to data line voltage levels by isolating each NAND string from its corresponding data line and electrically floating their respective channels. Alternatively, the voltage level applied to SGD might remain at the voltage level Vsgd_high at time t11.

At time t12, the voltage level applied to WLₛₑₗ and WLᵤₙₛₑₗ might be increased to a voltage level 560₅, further boosting the channel voltage level of the memory cells connected to the selected access line that are to remain at the L0-L3 data states. If SGD is decreased to Vsgd_low at time t11, the voltage level applied to BL4 might be increased to the inhibit voltage level Vinh between times t11 and t13, and might be increased concurrently with the increase of the voltage level applied to Wlₛₑₗ and WLᵤₙₛₑₗ at time t12. If the voltage level applied to SGD is alternatively maintained at Vsgd_high at time t11, the voltage level applied to BL4 might be increased to the inhibit voltage level Vinh prior to time t12 (e.g., after time t10 and prior to time t12) in order to isolate the NAND strings corresponding to the L4 data state from their corresponding data lines prior to increasing the voltage level applied to Wlₛₑₗ and WLᵤₙₛₑₗ at time t12. In either case, the increase of WLₛₑₗ and WLᵤₙₛₑₗ to the voltage level 560₅ might boost the channel voltage level of the memory cells connected to the selected access line that have the L4 desired data state. At time t13, SGD might be returned to the voltage level Vsgd_high. While channel voltage levels of memory cells connected to the selected access line that have the L5-L7 data states might be boosted at time t12 if SGD is at the voltage level Vsgd_low, these channels might be expected to discharge back to the enable voltage level Ven at time t13 upon being reconnected to their respective data lines.

At time t14 (e.g., after WLₛₑₗ and WLᵤₙₛₑₗ have reached the voltage level 560₅), the voltage level applied to SGD might be decreased to the voltage level Vsgd_low. This might serve to lock the respective channel voltage levels for each data state L0-L7 (e.g., the channel voltage levels of the pillars 450₀-450₇, respectively) before any changes are made to data line voltage levels by isolating each NAND string from its corresponding data line and electrically floating their respective channels. Alternatively, the voltage level applied to SGD might remain at the voltage level Vsgd_high at time t14.

At time t15, the voltage level applied to WLₛₑₗ and WLᵤₙₛₑₗ might be increased to a voltage level 560₆ further boosting the channel voltage level of the memory cells connected to the selected access line that are to remain at the L0-L4 data states. If SGD is decreased to Vsgd_low at time t14, the voltage level applied to BLs might be increased to the inhibit voltage level Vinh between times t14 and t16, and might be increased concurrently with the increase of the voltage level applied to Wlₛₑₗ and WLᵤₙₛₑₗ at time t15. If the voltage level applied to SGD is alternatively maintained at Vsgd_high at time t14, the voltage level applied to BLs might be increased to the inhibit voltage level Vinh prior to time t15 (e.g., after time t13 and prior to time t15) in order to isolate the NAND strings corresponding to the L5 data state from their corresponding data lines prior to increasing the voltage level applied to Wlₛₑₗ and WLᵤₙₛₑₗ at time t15. In either case, the increase of WLₛₑₗ and WLᵤₙₛₑₗ to the voltage level 560₆ might boost the channel voltage level of the memory cells connected to the selected access line that have the L5 desired data state. At time t16, SGD might be returned to the voltage level Vsgd_high. While channel voltage levels of memory cells connected to the selected access line that have the L6-L7 data states might be boosted at time t15 if SGD is at the voltage level Vsgd_low, these channels might be expected to discharge back to the enable voltage level Ven at time t16 upon being reconnected to their respective data lines.

At time t17 (e.g., after WLₛₑₗ and WLᵤₙₛₑₗ have reached the voltage level 560₆), the voltage level applied to SGD might be decreased to the voltage level Vsgd_low. This might serve to lock the respective channel voltage levels for each data state L0-L7 (e.g., the channel voltage levels of the pillars 450₀-450₇, respectively) before any changes are made to data line voltage levels by isolating each NAND string from its corresponding data line. Alternatively, the voltage level applied to SGD might remain at the voltage level Vsgd_high at time t17.

At time t18, the voltage level applied to WLₛₑₗ and WLᵤₙₛₑₗ might be increased to a pass voltage level Vpass, further boosting the channel voltage level of the memory cells connected to the selected access line that have the L0-L5 desired data states. If the voltage level applied to SGD is decreased to Vsgd_low at time t17, the voltage level applied to BL₆ might be increased to the inhibit voltage level Vinh between times t17 and t19, and might be increased concurrently with the increase of the voltage level applied to Wlₛₑₗ and WLᵤₙₛₑₗ at time t18. If the voltage level applied to SGD is alternatively maintained at Vsgd_high at time t17, the voltage level applied to BL₆ might be increased to the inhibit voltage level Vinh prior to time t18 (e.g., after time t16 and prior to time t18) in order to isolate the NAND strings corresponding to the L6 data state from their corresponding data lines prior to increasing the voltage level applied to Wlₛₑₗ and WLᵤₙₛₑₗ at time t18. In either case, the increase of WLₛₑₗ and WLᵤₙₛₑₗ to the pass voltage level Vpass might boost the channel voltage level of the memory cells connected to the selected access line that have L6 desired data state. At time t19, SGD might be returned to the voltage level Vsgd_high. While channel voltage levels of memory cells connected to the selected access line that have the L7 data state might be boosted at time t18 if SGD is at the voltage level Vsgd_low, these channels might be expected to discharge back to the enable voltage level Ven at time t19 upon being reconnected to their respective data lines.

At time t20, the voltage level applied to WLₛₑₗ might be increased to a programming voltage level Vpgm while maintaining the voltage level applied to WLᵤₙₛₑₗ at the pass voltage level Vpass. As a result, memory cells connected to the selected access line that have the L0 data state might be inhibited from programming with a first gate-to-body voltage difference, memory cells connected to the selected access line that have the L1 data state might be partially enabled for programming with a second gate-to-body voltage difference greater than the first gate-to-body voltage difference, memory cells connected to the selected access line that have the L2 data state might be partially enabled for programming with a third gate-to-body voltage difference greater than the second gate-to-body voltage difference, memory cells connected to the selected access line that have the L3 data state might be partially enabled for programming with a fourth gate-to-body voltage difference greater than the third gate-to-body voltage difference, memory cells connected to the selected access line that have the L4 data state might be partially enabled for programming with a fifth gate-to-body voltage difference greater than the fourth gate-to-body voltage difference, memory cells connected to the selected access line that have the L5 data state might be partially enabled for programming with a sixth gate-to-body voltage difference greater than the fifth gate-to-body voltage difference, memory cells connected to the selected access line that have the L6 data state might be partially enabled for programming with a seventh gate-to-body voltage difference greater than the sixth gate-to-body voltage difference, and memory cells connected to the selected access line that have the L7 data state might be fully enabled for programming with an eighth gate-to-body voltage difference greater than the seventh gate-to-body voltage difference.

At time t21, the voltage level applied to WLₛₑₗ might be decreased to the pass voltage level Vpass while maintaining the voltage level applied to WLᵤₙₛₑₗ at the pass voltage level Vpass. At time t22, WLₛₑₗ, WLᵤₙₛₑₗ, BL0-BL7, and SGD might be returned to their initial voltage levels. Subsequent to time t22, one or more additional programming pulses 562 might be applied in a similar manner. Alternatively, or in addition, an ISPP phase of the programming operation might be initiated to complete the programming of the selected memory cells of the programming operation. An ISPP phase of the programming operation, or other programming technique, might be utilized after applying the programming pulse 562 and without any intervening verify phase being performed.

The voltage levels 560₀, 560₁, 560₂, 560₃, 560₄, 560₅, 560₆, and the programming voltage level Vpgm, might be determined for the programming pulse 562 either experimentally, empirically or through simulation. The voltage levels might be chosen in order to produce a desired shift in threshold voltages of the various subsets of memory cells selected for the programming operation. Although only one programming pulse 562 is depicted in FIG. 5, one or more additional programming pulses might be applied in a similar manner, but having increasingly higher programming voltage levels for each successive programming pulse.

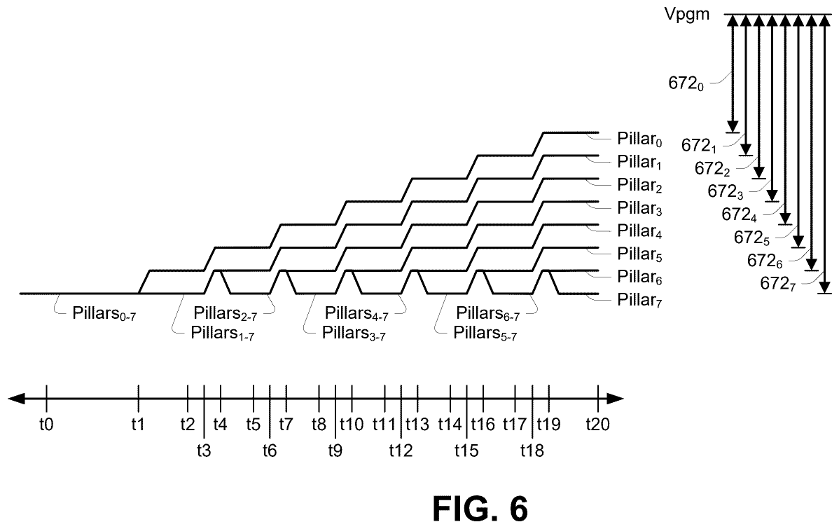

FIG. 6 is a timing diagram depicting channel voltage levels and gate-to-body voltage levels that might result from the application of the programming pulse 562 of FIG. 5. Times referenced in FIG. 6 correspond to the times discussed in FIG. 5. FIG. 6 might represent the channel voltage levels for embodiments decreasing the voltage level applied to SGD to the voltage level Vsgd_low at times t2, t5, 18, t11, t14, and t17, and subsequently returning it to Vsgd_high at times t4, t7, t10, t13, t16, and t19, respectively.

The trace Pillar₀ might represent the channel voltage level of the memory cells connected to the selected access line that are to remain at the L0 data state, the trace Pillar₁ might represent the channel voltage level of the memory cells connected to the selected access line that have the L1 desired data state, the trace Pillar₂ might represent the channel voltage level of the memory cells connected to the selected access line that have the L2 desired data state, the trace Pillar₃ might represent the channel voltage level of the memory cells connected to the selected access line that have the L3 desired data state, the trace Pillar₄ might represent the channel voltage level of the memory cells connected to the selected access line that have the L4 desired data state, the trace Pillar₅ might represent the channel voltage level of the memory cells connected to the selected access line that have the L5 desired data state, the trace Pillar₆ might represent the channel voltage level of the memory cells connected to the selected access line that have the L6 desired data state, and the trace Pillar₇ might represent the channel voltage level of the memory cells connected to the selected access line that have the L7 desired data state.

As depicted in FIG. 6, the different channel voltage levels for the different subsets of memory cells might produce different gate-to-body voltage differences 672. For example, the memory cells connected to the selected access line that are to remain at the L0 data state might have a first gate-to-body voltage difference 672₀, the memory cells connected to the selected access line that have the L1 desired data state might have a second gate-to-body voltage difference 672₁ greater than the first gate-to-body voltage difference 672₀, the memory cells connected to the selected access line that have the L2 desired data state might have a third gate-to-body voltage difference 672₂ greater than the second gate-to-body voltage difference 672₁, the memory cells connected to the selected access line that have the L3 desired data state might have a fourth gate-to-body voltage difference 672₃ greater than the third gate-to-body voltage difference 672₂, the memory cells connected to the selected access line that have the L4 desired data state might have a fifth gate-to-body voltage difference 672₄ greater than the fourth gate-to-body voltage difference 672₃, the memory cells connected to the selected access line that have the L5 desired data state might have a sixth gate-to-body voltage difference 672₅ greater than the fifth gate-to-body voltage difference 672₄, the memory cells connected to the selected access line that have the L6 desired data state might have a seventh gate-to-body voltage difference 672₆ greater than the sixth gate-to-body voltage difference 672₅, and the memory cells connected to the selected access line that have the L7 desired data state might have an eighth gate-to-body voltage difference 672₇ greater than the seventh gate-to-body voltage difference 672₆. The differing gate-to-body voltage differences 672 might be expected to affect the threshold voltages of the various memory cells selected for the programming operation to different degrees.

The resulting gate-to-body voltage differences 672 might be modified for a subsequent programming operation by selectively modifying a corresponding voltage level of the programming pulse 562, or by selectively modifying a corresponding voltage level of the programming pulse 562 and/or selectively modifying the programming voltage level Vpgm. For example, comparing FIGS. 5 and 6, it can be seen that an increase in the gate-to-body voltage difference 672₁ for L1 memory cells can be achieved by increasing the voltage level 560₁, e.g., its corresponding voltage level of the programming pulse 562 prior to being isolated from its data lines for the remainder of the programming pulse 562, as an increase in its corresponding voltage level 560₁ might produce a decrease in the resulting channel voltage level 672₁ of the L1 memory cells prior to applying the programming voltage level. A decrease in the gate-to-body voltage difference 672₁ for L1 memory cells can be achieved by decreasing its corresponding voltage level 560₁ as a decrease in its corresponding voltage level 560₁ might produce an increase in the resulting channel voltage level of the L1 memory cells prior to applying the programming voltage level.

Continuing with the foregoing example, an increase in the gate-to-body voltage difference 672₂ for L2 memory cells can be achieved by increasing its corresponding voltage level 560₂ and a decrease in the gate-to-body voltage difference 672₂ for L2 memory cells can be achieved by decreasing its corresponding voltage level 560₂, an increase in the gate-to-body voltage difference 672₃ for L3 memory cells can be achieved by increasing its corresponding voltage level 560₃ and a decrease in the gate-to-body voltage difference 672₃ for L3 memory cells can be achieved by decreasing its corresponding voltage level 560₃, an increase in the gate-to-body voltage difference 672₄ for L4 memory cells can be achieved by increasing its corresponding voltage level 560₄ and a decrease in the gate-to-body voltage difference 672₄ for L4 memory cells can be achieved by decreasing its corresponding voltage level 560₄, an increase in the gate-to-body voltage difference 672₅ for L5 memory cells can be achieved by increasing its corresponding voltage level 560₅ and a decrease in the gate-to-body voltage difference 672₅ for L5 memory cells can be achieved by decreasing its corresponding voltage level 560₅, and an increase in the gate-to-body voltage difference 672₆ for L6 memory cells can be achieved by increasing its corresponding voltage level 560₆ and a decrease in the gate-to-body voltage difference 672₆ for L6 memory cells can be achieved by decreasing its corresponding voltage level 560₆.

For embodiments further selectively modifying the programming voltage level for a programming pulse (e.g., an initial programming pulse) of a subsequent programming operation, increases in the programming voltage level Vpgm can generally produce an increase in the gate-to-body voltage difference for all data states, while decreases in the programming voltage level Vpgm can generally produce a decrease in the gate-to-body voltage difference for all data states.

For individual data states, an increase in the gate-to-body voltage difference might be achieved by increasing the programming voltage level Vpgm and maintaining a channel voltage level, increasing the programming voltage level Vpgm and decreasing the channel voltage level, maintaining the programming voltage level Vpgm and decreasing the channel voltage level, increasing the programming voltage level Vpgm and increasing the channel voltage level by a magnitude less than the magnitude of the increase of the programming voltage level Vpgm, or decreasing the programming voltage level Vpgm and decreasing the channel voltage level by a magnitude greater than the magnitude of the decrease of the programming voltage level Vpgm. Similarly, for individual data states, a decrease in the gate-to-body voltage difference might be achieved by decreasing the programming voltage level Vpgm and maintaining a channel voltage level, decreasing the programming voltage level Vpgm and increasing the channel voltage level, maintaining the programming voltage level Vpgm and increasing the channel voltage level, decreasing the programming voltage level Vpgm and decreasing the channel voltage level by a magnitude less than the magnitude of the decrease of the programming voltage level Vpgm, or increasing the programming voltage level Vpgm and increasing the channel voltage level by a magnitude greater than the magnitude of the increase of the programming voltage level Vpgm.

Although data intended for programming to memory cells might not include similarly sized distributions of each of the possible data states, and might be devoid of one or more of the data states, it is typical to utilize data randomization prior to programming such that the data programmed to the memory cells might approach a random distribution of all of the possible data states. Data randomization is often used to mitigate coupling effects between closely neighboring memory cells that can disturb the intended data states. As a result of data randomization, each possible data state to which a memory cell can be programmed in a programming operation might be programmed to a similar (e.g., the same) number of memory cells. As such, while memory cells to be programmed to any one data state could contain a number of memory cells ranging from zero to a total number of memory cells selected for a programming operation, a substantially equal (e.g., equal) number of memory cells might be programmed to each of the data states. For example, if 4K (e.g., 4096) memory cells are each programmed to one of eight possible data states (e.g., data states L0-L7) utilizing data randomization, memory cells to be programmed to the L7 data state might be expected to contain a number of memory cells substantially equal to (e.g., equal to) 512 memory cells, memory cells to be programmed to the L6 data state might be expected to contain a number of memory cells substantially equal to (e.g., equal to) 512 memory cells, memory cells to be programmed to the L5 data state might be expected to contain a number of memory cells substantially equal to (e.g., equal to) 512 memory cells, and so on.

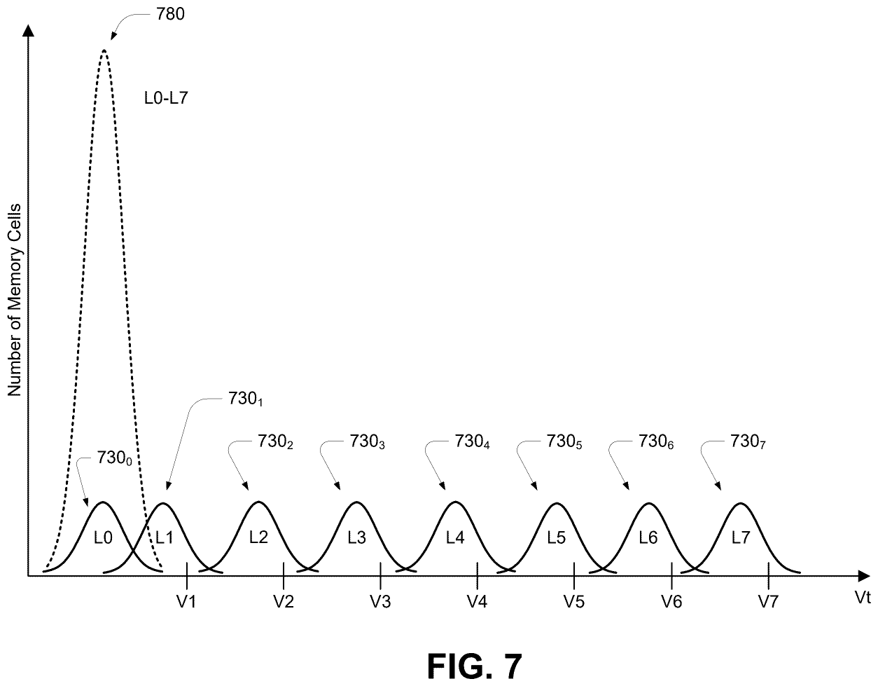

FIG. 7 is a conceptual depiction of threshold voltage distributions of a plurality of memory cells that might result from the application of a programming pulse 562 in accordance with an embodiment. In FIG. 7, the threshold voltage distribution 780 might represent the threshold voltage distribution of a plurality of memory cells selected for programming to one of a plurality of possible data states (e.g., to one of the data states L0-L7), but prior to programming, e.g., with each memory cell of the plurality of memory cells in the erased data state. Following application of the programming pulse 562 such as described with reference to FIG. 5, the memory cells connected to the selected access line that are to remain at the L0 data state might remain at the L0 data state as represented by the threshold voltage distribution 730₀ due to being inhibited from programming. Note that the threshold voltage distribution 730₀ might correspond to the threshold voltage distribution 330% of FIG. 3. The memory cells connected to the selected access line that have the L1 desired data state might shift to the interim threshold voltage distribution 730₁ due to being partially enabled for programming. The memory cells connected to the selected access line that have the L2 desired data state might shift to the interim threshold voltage distribution 730₂ due to being partially enabled for programming to a higher degree than the L1 memory cells. The memory cells connected to the selected access line that have the L3 desired data state might shift to the interim threshold voltage distribution 730₃ due to being partially enabled for programming to a higher degree than the L2 memory cells. The memory cells connected to the selected access line that have the L4 desired data state might shift to the interim threshold voltage distribution 730₄ due to being partially enabled for programming to a higher degree than the L3 memory cells. The memory cells connected to the selected access line that have the L5 desired data state might shift to the interim threshold voltage distribution 730₅ due to being partially enabled for programming to a higher degree than the L4 memory cells. The memory cells connected to the selected access line that have the L6 desired data state might shift to the interim threshold voltage distribution 730₆ due to being partially enabled for programming to a higher degree than the L5 memory cells. The memory cells connected to the selected access line that have the L7 desired data state might shift to the interim threshold voltage distribution 730₇ due to being fully enabled for programming.

As depicted in FIG. 7, the result of applying the programming pulse 562 might not shift all of the memory cells to their desired range of threshold voltages. A verify phase of the programming operation might be performed following application of the programming pulse 562 to determine whether individual memory cells are deemed to have reached respective threshold voltages corresponding to their respective desired data states. In general, a verify phase might be performed by applying one or more verify voltage levels to the selected access line and determining whether a memory cell is deemed to be activated or deactivated in response to its corresponding verify voltage level. A memory cell might be deemed to pass verify if it is deemed to be deactivated in response to its corresponding verify voltage level, e.g., a memory cell that has reached its desired data state. As a result of the verify phase, the memory might determine how many memory cells having the L1 desired data state passed verify in response to the VI verify voltage level, how many memory cells having the L2 desired data state passed verify in response to the V2 verify voltage level, how many memory cells having the L3 desired data state passed verify in response to the V3 verify voltage level, how many memory cells having the L4 desired data state passed verify in response to the V4 verify voltage level, how many memory cells having the L5 desired data state passed verify in response to the V5 verify voltage level, how many memory cells having the L6 desired data state passed verify in response to the V6 verify voltage level, and how many memory cells having the L7 desired data state passed verify in response to the V7 verify voltage level.

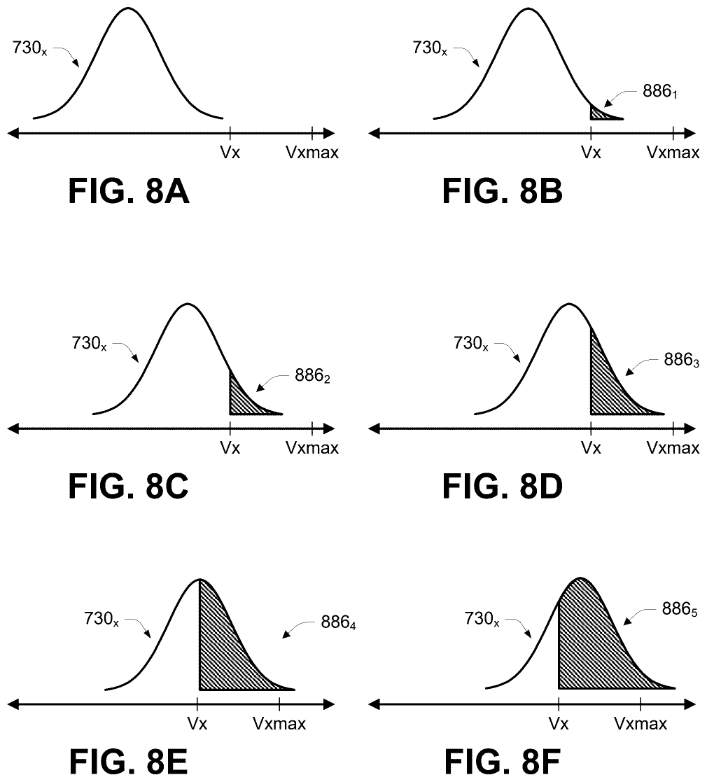

Although a verify phase generally does not determine a maximum threshold voltage of a memory cell being verified, it might generally be expected that the threshold voltages of memory cells for each data state would fall into a normal distribution. As such, an indication of the number of memory cells passing verify for one data state might be informative as to an expected maximum threshold voltage of the memory cells passing verify for that data state. FIGS. 8A-8F illustrate this concept.

FIGS. 8A-8F are conceptual depictions of threshold voltage distributions of a plurality of memory cells as could be used with embodiments. FIGS. 8A-8F depict how an indication of a number of memory cells passing verify could be used to indicate an expected maximum threshold voltage of the memory cells having a same desired data state. Each of the FIGS. 8A-8F considers an example for a data state X, which might be any of the data states higher than the data state L0. The data state X might have a desired width (e.g., a width 331 of FIG. 3) of its final threshold voltage distribution extending from its corresponding verify voltage level Vx to a corresponding voltage level Vxmax. The desired width, e.g., Vxmax-Vx, might be less than a width of the threshold voltage distribution of the memory cells prior to programming, e.g., the width of the threshold voltage distribution 780 of FIG. 7. The interim threshold voltage distribution 730_{X} might be expected to have a width substantially equal to the width of the threshold voltage distribution 780.

FIG. 8A depicts an instance of having zero memory cells passing verify for the data state X. In such a case, the entirety of the interim threshold voltage distribution 730_{X} might be expected to have threshold voltage levels lower than its verify voltage level Vx. A larger shift in threshold voltage levels in response to an initial programming pulse could result in more efficient programming, e.g., a reduction in programming pulses and/or programming time, which might indicate a desire to increase a gate-to-body voltage difference for the data state X in a subsequent programming operation.

FIG. 8B depicts an instance of having a first number of memory cells passing verify for the data state X, indicated by the shaded region 886₁ of the interim threshold voltage distribution 780_{X}. In such a case, one portion of the interim threshold voltage distribution 730_{X} might be expected to have threshold voltage levels lower than its verify voltage level Vx while a second, smaller portion of the interim threshold voltage distribution 730_{X} might be expected to have threshold voltage levels higher than its verify voltage level Vx. Because of the significant difference between an expected maximum threshold voltage level of the interim threshold voltage distribution 730_{X} and the voltage level Vxmax, a larger shift in threshold voltage levels in response to an initial programming pulse could result in more efficient programming, which might indicate a desire to increase a gate-to-body voltage difference for the data state X in a subsequent programming operation. The increase in gate-to-body voltage difference in the example of FIG. 8B might be equal to or lower than the increase in gate-to-body voltage difference in the example of FIG. 8A.

FIG. 8C depicts an instance of having a second number of memory cells passing verify for the data state X, greater than the first number and indicated by the shaded region 886₂ of the interim threshold voltage distribution 780_{X}. In such a case, one portion of the interim threshold voltage distribution 730_{X} might be expected to have threshold voltage levels lower than its verify voltage level Vx while a second, smaller portion of the interim threshold voltage distribution 730_{X} might be expected to have threshold voltage levels higher than its verify voltage level Vx. Because there is still a difference between an expected maximum threshold voltage level of the interim threshold voltage distribution 730_{X} and the voltage level Vxmax, a larger shift in threshold voltage levels in response to an initial programming pulse could result in more efficient programming, e.g., a reduction in programming pulses and/or programming time, which might indicate a desire to increase a gate-to-body voltage difference for the data state X in a subsequent programming operation. The increase in gate-to-body voltage difference in the example of FIG. 8C might be equal to or lower than the increase in gate-to-body voltage difference in the example of FIG. 8B. However, the shift in threshold voltage levels might alternatively be deemed sufficiently close to an optimum shift, e.g., extending to Vxmax, that a subsequent programming operation might utilize no modification of the gate-to-body voltage difference for the data state X.

FIG. 8D depicts an instance of having a third number of memory cells passing verify for the data state X, greater than the second number and indicated by the shaded region 886₃ of the interim threshold voltage distribution 780_{X}. In such a case, one portion of the interim threshold voltage distribution 730_{X} might be expected to have threshold voltage levels lower than its verify voltage level Vx while a second, smaller portion of the interim threshold voltage distribution 730_{X} might be expected to have threshold voltage levels higher than its verify voltage level Vx. Because the difference between an expected maximum threshold voltage level of the interim threshold voltage distribution 730_{X} and the voltage level Vxmax might be deemed de minimis, the shift in threshold voltage levels might be deemed sufficiently close to an optimum shift, e.g., extending to Vxmax, that a subsequent programming operation might utilize no modification of the gate-to-body voltage difference for the data state X.

FIG. 8E depicts an instance of having a fourth number of memory cells passing verify for the data state X, greater than the third number and indicated by the shaded region 886₄ threshold voltage distribution 730_{X} might be expected to have threshold voltage levels lower than its verify voltage level Vx while a second portion of the interim threshold voltage distribution 730_{X} might be expected to have threshold voltage levels higher than its verify voltage level Vx. Because the expected maximum threshold voltage level of the interim threshold voltage distribution 730_{X} is higher than the voltage level Vxmax, a smaller shift in threshold voltage levels in response to an initial programming pulse could result in more efficient programming, e.g., a reduction in the width of the final threshold voltage distribution (e.g., a threshold voltage distribution 330), which might indicate a desire to decrease a gate-to-body voltage difference for the data state X in a subsequent programming operation.

FIG. 8F depicts an instance of having a fifth number of memory cells passing verify for the data state X, greater than the fourth number and indicated by the shaded region 886₄ of the interim threshold voltage distribution 780_{X}. In such a case, one portion of the interim threshold voltage distribution 730_{X} might be expected to have threshold voltage levels lower than its verify voltage level Vx while a second, larger portion of the interim threshold voltage distribution 730_{X} might be expected to have threshold voltage levels higher than its verify voltage level Vx. Because the expected maximum threshold voltage level of the interim threshold voltage distribution 730_{X} is higher than the voltage level Vxmax, a smaller shift in threshold voltage levels in response to an initial programming pulse could result in more efficient programming, e.g., a reduction in the width of the final threshold voltage distribution (e.g., a threshold voltage distribution 330), which might indicate a desire to decrease a gate-to-body voltage difference for the data state X in a subsequent programming operation. The decrease in gate-to-body voltage difference in the example of FIG. 8F might be equal to or higher than the decrease in gate-to-body voltage difference in the example of FIG. 8E.

The number of memory cells passing verify for a data state might provide an indication of what gate-to-body voltage difference might provide a desired shift in threshold voltage. For example, if zero or few memory cells pass verify for the data state X such as depicted in FIGS. 8A and 8B, this might indicate a desire to increase the gate-to-body voltage difference 672_{X} in a subsequent programming operation. Conversely, if too many memory cells pass verify for the data state X such as depicted in FIGS. 8E and 8F, this might indicate a desire to decrease the gate-to-body voltage difference 672_{X} in a subsequent programming operation.

The decision process to maintain, increase or decrease a gate-to-body voltage difference for a data state for a subsequent programming operation might utilize a lookup table. A lookup table might represent a relationship between a number of memory cells passing verify for a single data state and a desired change in the gate-to-body voltage difference for an initial programming pulse of a subsequent programming operation. Table 2 provides one example of a lookup table that might be utilized with embodiments.

TABLE 2
Change in Gate-to-Body Voltage difference (ΔVgb) as a Function
of a Number of Memory Cells Passing Verify for a Data State (P_{X})

| P_{X} | ΔVgb |
|---|---|
| P_{X} < T₁ | V+ |
| T₁ <= P_{X} <= T₂ | 0 |
| P_{X} > T₂ | V− |

In Table 2, T₁ might represent a first threshold value, T₂ might represent a second threshold value greater than or equal to T₁, V+ might represent some positive voltage value, V− might represent some negative voltage value, and X might represent any data state of the programming operation other than the lowest data state (e.g., to be inhibited from programming during the programming operation) and the highest data state (e.g., to be fully enabled for programming during the programming operation). The voltage values V+ and V− might have different or equal magnitudes. In using Table 2, the gate-to-body voltage difference for data state X in a subsequent programming operation might be increased by the magnitude of the voltage value V+ in response to a number of memory cells passing verify for data state X being less than the first threshold value T₁, decreased by the magnitude of the voltage value V− in response to a number of memory cells passing verify for data state X being greater than the second threshold value T₂, and maintained at its prior (e.g., initial) value in response to a number of memory cells passing verify for data state X being greater than or equal to the first threshold value T₁ and less than or equal to the second threshold value T₂. Note that the desired change in gate-to-body voltage difference can directly indicate a desired change in the corresponding voltage level of a programming pulse, and that a lookup table could be developed for a change in corresponding voltage level as a function of the number of memory cells passing verify.

While Table 2 depicts only two threshold values T₁ and T₂, additional threshold values could be used to facilitate use of different magnitudes of change in response to different numbers of memory cells passing verify. Table 3 depicts such an embodiment.

TABLE 3
Change in Gate-to-Body Voltage difference (ΔVgb) as a Function
of a Number of Memory Cells Passing Verify for a Data State (P_{X})

| P_{X} | ΔVgb |
|---|---|
| P_{X} < T₁ | V++ |
| T₁ <= P_{X} < T₂ | V+ |
| T₂ <= P_{X} <= T₃ | 0 |
| T₃ < P_{X} <= T₄ | V− |
| P_{X} > T₄ | V−− |

In Table 3, T₁ might represent a first threshold value, T₂ might represent a second threshold value greater than T₁, T₃ might represent a third threshold value greater than or equal to T₂, T₄ might represent a fourth threshold value greater than T₃, V+ might represent some positive voltage value, V++ might represent some positive voltage value higher than V+, V− might represent some negative voltage value, V−− might represent some negative voltage value lower than V−, and X might represent any data state of the programming operation other than the lowest data state (e.g., to be inhibited from programming during the programming operation) and the highest data state (e.g., to be fully enabled for programming during the programming operation). The voltage values V+ and V− might have different or equal magnitudes and the voltage values V++ and V−− might have different or equal magnitudes. In using Table 3, the gate-to-body voltage difference for data state X in a subsequent programming operation might be increased by the magnitude of the voltage value V++ in response to a number of memory cells passing verify for data state X being less than the first threshold value T₁, increased by the magnitude of the voltage value V+ in response to a number of memory cells passing verify for data state X being less than the second threshold value T₂ and greater than or equal to the first threshold value T₁, decreased by the magnitude of the voltage value V− in response to a number of memory cells passing verify for data state X being greater than the third threshold value T₃ and less than or equal to the fourth threshold value T₄, decreased by the magnitude of the voltage value V−− in response to a number of memory cells passing verify for data state X being greater than the fourth threshold value T₄, and maintained at its prior (e.g., initial) value in response to a number of memory cells passing verify for data state X being greater than or equal to the second threshold value T₂ and less than or equal to the third threshold value T₃. Other embodiments might use additional threshold values in a similar manner.

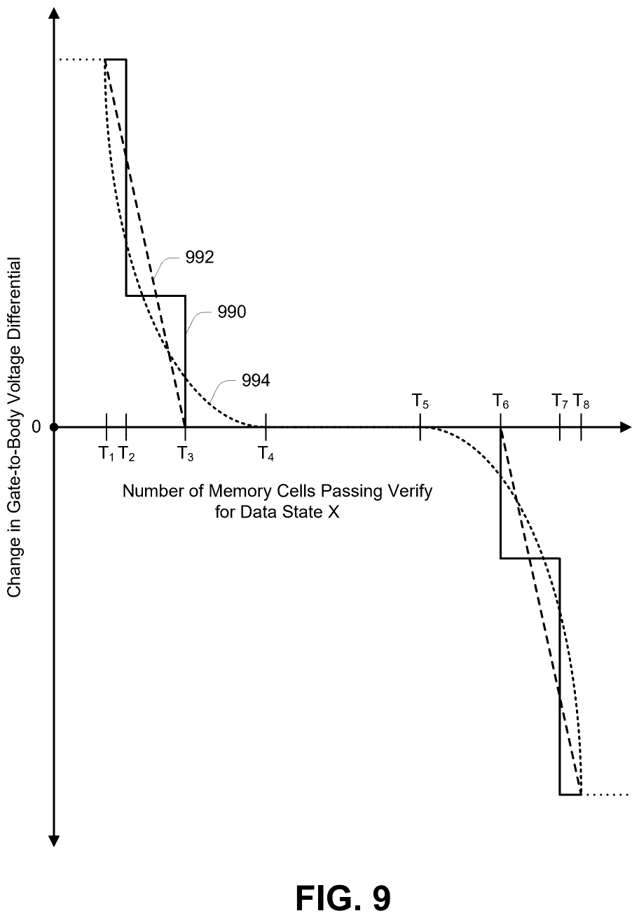

As an alternative to lookup tables, the determination of desired change in gate-to-body voltage difference could be defined as a function of the number of memory cells passing verify for a data state, for some embodiments. FIG. 9 depicts examples of functions that might be used to define the desired change in gate-to-body voltage difference as a function of the number of memory cells passing verify for a data state. The threshold value T₁ might be greater than or equal to zero.

In FIG. 9, the function 990 might represent a step function that might mimic the use of a lookup table. In this example, the step function 990 might define a zero change in gate-to-body voltage difference between the threshold values T₃ and T₆, a first positive change in gate-to-body voltage difference between the threshold values T₂ and T₃, a second positive change greater than the first positive change in gate-to-body voltage difference between the threshold values T₁ and T₂, a first negative change in gate-to-body voltage difference between the threshold values T₆ and T₇, and a second negative change less than the first negative change in gate-to-body voltage difference between the threshold values T₇ and T₈. The steps of the step function 990 might be of the same or different heights (e.g., change in gate-to-body voltage difference) and widths (e.g., number of memory cells passing verify). Any number of memory cells less than the threshold value T₁ might have the magnitude of positive change that the step function 990 defines for the threshold value T₁, and any number of memory cells greater than the threshold value Ts might have the magnitude of negative change that the step function 990 defines for the threshold value T₈.

In FIG. 9, the function 992 might represent a linear function that might provide higher granularity over the step function 990. In this example, the linear function 992 might define a zero change in gate-to-body voltage difference between the threshold values T₃ and T₆, increasing magnitudes of positive change in gate-to-body voltage difference from the threshold value T₃ to the threshold value T₁, and increasing magnitudes of negative change in gate-to-body voltage difference from the threshold value To to the threshold value T₈. Any number of memory cells less than the threshold value T₁ might have the magnitude of positive change that the linear function 992 defines for the threshold value T₁, and any number of memory cells greater than the threshold value T₈ might have the magnitude of negative change that the linear function 992 defines for the threshold value T₈.

In FIG. 9, the function 994 might represent a curvilinear function that might provide higher granularity over the step function 990. In this example, the curvilinear function 994 might define a zero change in gate-to-body voltage difference between the threshold values T₄ and T₅, increasing magnitudes of positive change in gate-to-body voltage difference from the threshold value T₄ to the threshold value T₁, and increasing magnitudes of negative change in gate-to-body voltage difference from the threshold value T₈ to the threshold value T₈. Any number of memory cells less than the threshold value T₁ might have the magnitude of positive change that the curvilinear function 994 defines for the threshold value T₁, and any number of memory cells greater than the threshold value T₈ might have the magnitude of negative change that the curvilinear function 994 defines for the threshold value T₈.

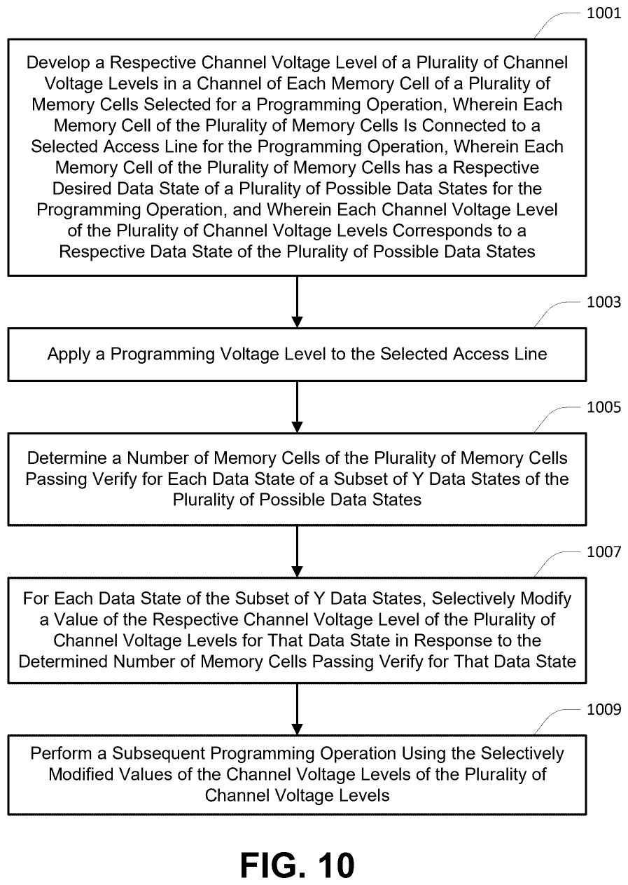

FIG. 10 is a flowchart of a method of operating a memory in accordance with an embodiment. The method might represent actions associated with a programming operation performed by the memory. The method might be in the form of computer-readable instructions, e.g., stored to the instruction registers 128. Such computer-readable instructions might be executed by a controller, e.g., the control logic 116, to cause the relevant components of the memory to perform the method. The method of FIG. 10 might apply to embodiments seeking to modify the developed gate-to-body voltage differences for a subsequent programming operation that might be independent of any changes to the programming voltage level.

At 1001, a respective channel voltage level of a plurality of channel voltage levels might be developed in a channel of each memory cell of a plurality of memory cells selected for a programming operation. Each memory cell of the plurality of memory cells might be connected to a selected access line for the programming operation. Each memory cell of the plurality of memory cells might have a respective desired data state of a plurality of possible data states for the programming operation. Each channel voltage level of the plurality of channel voltage levels might correspond to a respective data state of the plurality of possible data states.

At 1003, a programming voltage level might be applied to the selected access line. The programming voltage level might be applied to the selected access line while each memory cell has the channel voltage level corresponding to its desired data state of the plurality of data states. The programming voltage level might be a start programming voltage level of the programming operation, e.g., a programming voltage level of an initial programming pulse of the programming operation.

At 1005, a number of memory cells of the plurality of memory cells passing verify might be determined for each data state of a subset of Y data states of the plurality of possible data states. The subset of Y data states might include one or more data states of the plurality of data states other than the lowest and highest data states of the plurality of data states. For example, for a programming operation of an MLC memory having four possible data states L0-L3, the subset of Y data states might include one or both of the data states L1 and L2. For a programming operation of a TLC memory having eight possible data states L0-L7, the subset of Y data states might include one or more of the data states L1-L6. As such, where the number of possible data states for a programming operation is the integer value D, the integer value of Y might satisfy the condition 1<=Y<=(D=2). For some embodiments, the subset of Y data states includes all possible data states other than the lowest data state and the highest data state, e.g., Y=D=2.

At 1007, for each data state of the subset of Y data states, a value of the respective channel voltage level of the plurality of channel voltage levels for that data state might be selectively modified in response to the determined number of memory cells passing verify for that data state. For example, in response to the determined number of memory cells passing verify for that data state being less than a respective first threshold value, the respective channel voltage level for that data state might be increased (e.g., its corresponding voltage level 560 might be decreased); in response to the determined number of memory cells passing verify for that data state being greater than a respective second threshold value, the respective channel voltage level for that data state might be decreased (e.g., its corresponding voltage level 560 might be increased); and in response to the determined number of memory cells passing verify for that data state being greater than or equal to its respective first threshold value and less than or equal to its respective second threshold value, the respective channel voltage level for that data state might not be modified (e.g., its corresponding voltage level 560 might remain unchanged).

The respective second threshold value for a data state might be greater than or equal to the respective first threshold value for that data state. The respective first and second threshold values for one data state might be the same or different than the respective first and second threshold values, respectively, of a different data state. While benefits might be expected from evaluating all data states other than the lowest data state (e.g., inhibited from programming) and the highest data state (e.g., fully enabled for programming), the evaluation might preclude one or more additional data states, e.g., if the additional benefit is deemed to be de minimis or is deemed to be too costly in time and/or controller loading. Information indicative of the selectively modified values might be stored to the memory, e.g., to the trim register 127, for subsequent use. Note that changes in respective channel voltage levels can be effected by changing the corresponding voltage levels 560 of the programming pulse for the various data states as discussed with reference to FIG. 6.

At 1009, a subsequent programming operation might be performed using the selectively modified values of the channel voltage levels of the plurality of channel voltage levels. The subsequent programming operation might be performed on the same plurality of memory cells, the subsequent programming operation might be performed on a different plurality of memory cells of the same block of memory cells (e.g., which might be from a same or different physical page of memory cells), or the subsequent programming operation might be performed on a different plurality of memory cells of a different block of memory cells. In general, the modified values of the channel voltage levels of the plurality of channel voltage levels could be used to program any memory cells that might be expected to perform in a similar manner to the plurality of memory cells verified at 1005.

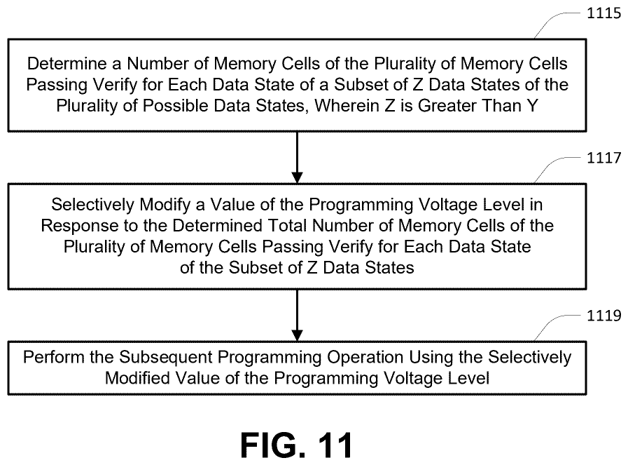

FIG. 11 is a flowchart of a method of operating a memory in accordance with a further embodiment. The method might represent actions associated with a programming operation performed by the memory. The method might be in the form of computer-readable instructions, e.g., stored to the instruction registers 128. Such computer-readable instructions might be executed by a controller, e.g., the control logic 116, to cause the relevant components of the memory to perform the method. The method of FIG. 11 might be utilized in conjunction with embodiments such as described with reference to FIG. 10.

At 1115, a number of memory cells of the plurality of memory cells passing verify might be determined for each data state of a subset of Z data states of the plurality of possible data states. The integer value Z might be greater than the integer value Y. Where the number of possible data states for a programming operation is the integer value D, the integer value of Z might satisfy the condition Y<Z<=D. Note that the actions of 1115 might be performed concurrently with 1005 of FIG. 10. For some embodiments, the subset of Z data states might include all possible data states other than the lowest data state, e.g., Z=D−1, or might include all possible data states, e.g., Z=D.

At 1117, a value of the programming voltage level might be selectively modified in response to the determined total number of memory cells of the plurality of memory cells passing verify for each data state of the subset of Z data states. For one example, in response to the determined total number of memory cells passing verify for each data state of the subset of Z data states being less than a first threshold value for the subset of Z data states, the programming voltage level might be increased; in response to the determined total number of memory cells passing verify for each data state of the subset of Z data states being greater than a second threshold value for the subset of Z data states, the programming voltage level might be decreased; and in response to the determined total number of memory cells passing verify for each data state of the subset of Z data states being greater than or equal to its first threshold value and less than or equal to its second threshold value, the programming voltage level might not be modified, e.g., might remain unchanged. The second threshold value for the subset of Z data states might be greater than or equal to the first threshold value for the subset of Z data states.

Note that for embodiments selectively modifying the value of the programming voltage level at 1117, selectively modifying the value of the respective channel voltage level for a data state at 1007 in FIG. 10 might further include selectively modifying the value of the respective channel voltage level for that data state in further response to the selectively modified value of the programming voltage level. Consider the example where the determined number of memory cells passing verify for a particular data state indicates a change in the value of the respective channel voltage level for that data state that is configured to contribute a change in gate-to-body voltage difference of ΔVgb1 for that data state, and where the determined number of memory cells of the plurality of memory cells passing verify for each data state of the subset of Z data states indicates a change in the value of the programming voltage level that is configured to contribute a change in gate-to-body voltage difference of ΔVgb2 for all data states. In such a case, the value of the respective channel voltage level for the particular data state might be modified such that it is configured to contribute a change in gate-to-body voltage difference of ΔVgb3, such that a combined change in gate-to-body voltage difference, e.g., (ΔVgb3+ΔVgb2), is equal to, or approaches, ΔVgb1. Note that, whether using lookup tables or otherwise, there might be no value of the respective channel voltage level for the particular data state that is configured to contribute a change in gate-to-body voltage difference of ΔVgb3 for that data state. In such a case, the available value of the respective channel voltage level for the particular data state that is configured to contribute a change in gate-to-body voltage difference that is nearest to ΔVgb3, or that is configured to produce a combined change in gate-to-body voltage difference that is nearest to ΔVgb1, might be selected. The selection from the available values of respective channel voltage levels might further be guided by a desire for the resulting interim threshold voltage distribution 730 having a highest expected threshold voltage value that is lower than a highest desired threshold voltage value of the final threshold voltage distribution 330, e.g., for positive values of to ΔVgb1, the selected available value of the respective channel voltage level for the particular data state might be configured to produce a combined change in gate-to-body voltage difference that is nearest to ΔVgb1 without exceeding ΔVgb1. In this manner, a desired shift of the threshold voltage distribution might be attained in the subsequent programming operation. Note that the value of ΔVgb1 and the value of ΔVgb2 might each be positive, negative, or zero.

Information indicative of the selectively modified value of the programming voltage level might be stored to the memory, e.g., to the trim register 127, for subsequent use. At 1119, the subsequent programming operation might be performed using the selectively modified value of the programming voltage level.

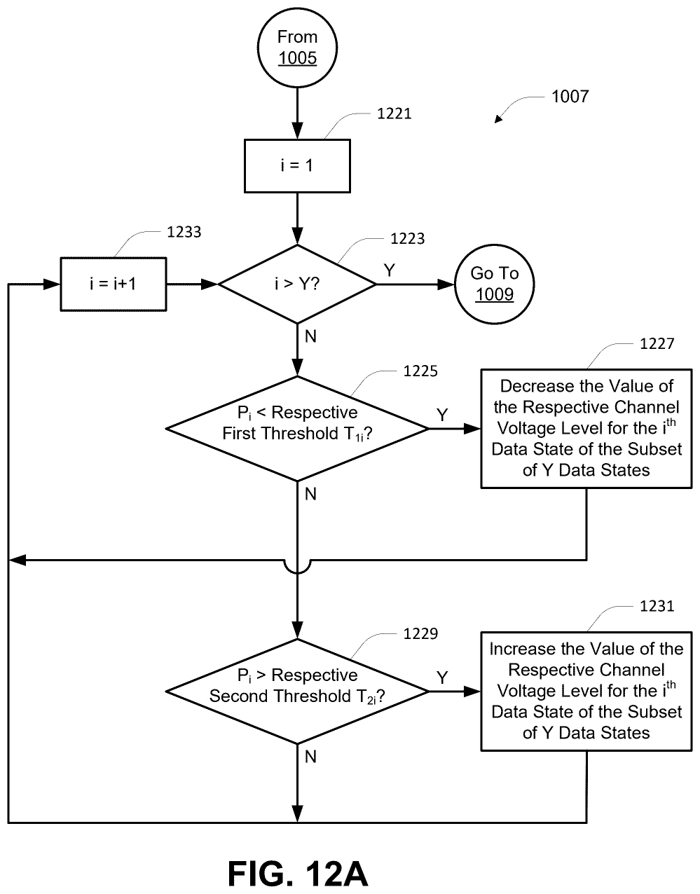

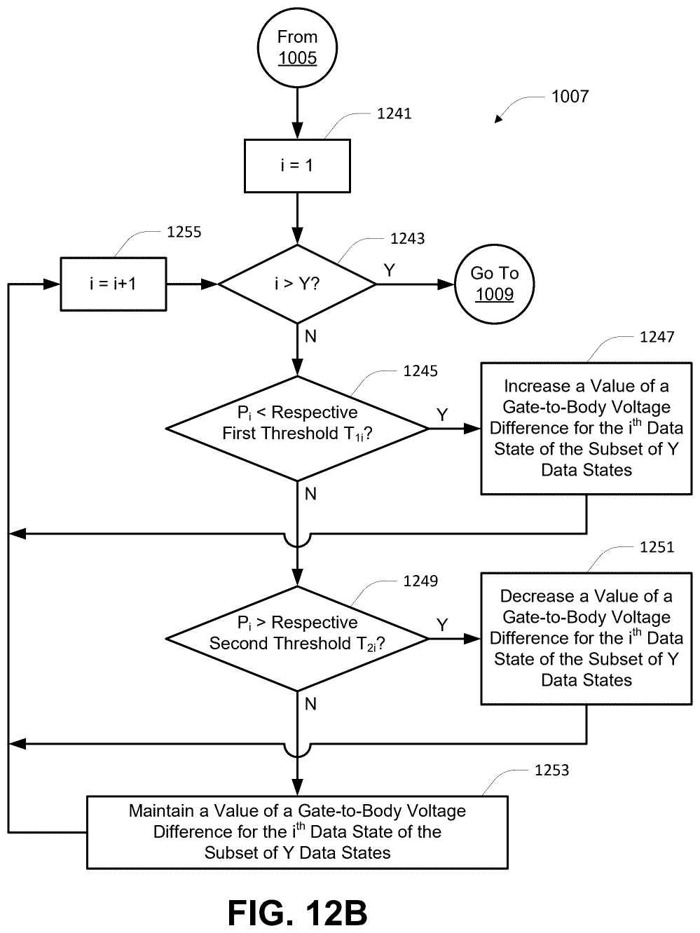

FIGS. 12A-12B are flowcharts of methods of operating a memory in accordance with alternate embodiments. The methods might represent actions associated with a programming operation performed by the memory. The methods might be in the form of computer-readable instructions, e.g., stored to the instruction registers 128. Such computer-readable instructions might be executed by a controller, e.g., the control logic 116, to cause the relevant components of the memory to perform the methods. The methods of FIGS. 12A-12B might be utilized with embodiments such as described with reference to FIG. 10. In particular, the methods of FIGS. 12A-12B might provide additional detail to selectively modifying the values of the respective channel voltage levels for the data states at 1007 in FIG. 10.

The method of FIG. 12A might correspond to an embodiment using a same programming voltage level for the subsequent programming operation. At 1221, having determined the number of memory cells of the plurality of memory cells passing verify for each data state of the subset of Y data states at 1005 of FIG. 10, an integer value i might be equal to 1. The process of 1223-1231 might be repeated for each value of i from 1 to Y. At 1223, it might be determined whether i is greater than Y. In response to i not being greater than Y at 1223, the process might proceed to 1225.

At 1225, it might be determined whether the determined number of memory cells passing verify for the i^{th} data state (Pᵢ) of the subset of Y data states is less than the respective first threshold for the i^{th} data state (T₁ᵢ). In response to the determined number of memory cells passing verify for the i^{th} data state (Pᵢ) being less than the respective first threshold for the i^{th} data state (T₁ᵢ) at 1225, the value of its respective channel voltage level might be decreased at 1227, e.g., its corresponding voltage level 560ᵢ of the programming pulse 562 might be increased. The process might then proceed to 1233. In response to the determined number of memory cells passing verify for the i^{th} data state (Pᵢ) being greater than or equal to the respective first threshold for the i^{th} data state (T₁ᵢ) at 1225, the process might proceed to 1229. Note that while the value of i might correspond directly to the data state designations used in FIG. 3, e.g., i=1 corresponds to data state L1, i=2 corresponds to data state L2, and so on, this correspondence is not necessary, especially for embodiments where Y<(D−2).

At 1229, it might be determined whether the determined number of memory cells passing verify for the i^{th} data state (Pᵢ) of the subset of Y data states is greater than the respective second threshold for the i^{th} data state (T₂ᵢ). In response to the determined number of memory cells passing verify for the i^{th} data state (Pᵢ) being greater than the respective second threshold for the i^{th} data state (T₂ᵢ) at 1229, the value of its respective channel voltage level might be increased at 1231, e.g., its corresponding voltage level 560ᵢ of the programming pulse 562 might be decreased. The process might then proceed to 1233. In response to the determined number of memory cells passing verify for the i^{th} data state (Pᵢ) being less than or equal to the respective second threshold for the i^{th} data state (T₂ᵢ) at 1229, the process might proceed to 1233, e.g., without modifying the value of the respective channel voltage level for the i^{th} data state.

At 1233, the value of i might be incremented by 1 (e.g., a step of 1) and the process might return to 1223 to repeat the process of 1223-1231 for each remaining value of i that is less than or equal to Y.

In response to i being greater than Y at 1223, the process might return to 1009 of FIG. 10 to perform the subsequent programming operation using the selectively modified values of the channel voltage levels of the plurality of channel voltage levels.

Although the embodiment of FIG. 12A only looked to two threshold values for each data state, it could equally apply to embodiments utilizing more than two threshold values. For example, the first threshold Thi of FIG. 12A could correspond to the threshold T₂ of Table 3 in determining whether a decrease in channel voltage level is desired, and the second threshold T₂ i of FIG. 12A could correspond to the threshold T₃ of Table 3 in determining whether an increase in channel voltage level is desired. Additional thresholds and logic could be used to determine the magnitudes of the increase or decrease in channel voltage level.

Although the flowchart of FIG. 12A depicts the consideration of individual data states to occur sequentially in a particular order, these acts could be performed in a different order, or they could be performed concurrently for two or more, including up to all, of the data states of the subset of Y data states. In addition, while the number of memory cells passing verify for a data state is evaluated sequentially against its respective first and second thresholds in a particular order, this order could be reversed, or the evaluations could be performed concurrently.

The method of FIG. 12B might correspond to an embodiment using a same or different programming voltage level for the subsequent programming operation. At 1241, having determined the number of memory cells of the plurality of memory cells passing verify for each data state of the subset of Y data states at 1005 of FIG. 10, an integer value i might be equal to 1. The process of 1243-1253 might be repeated for each value of i from 1 to Y. At 1243, it might be determined whether i is greater than Y. In response to i not being greater than Y at 1243, the process might proceed to 1245.

At 1245, it might be determined whether the determined number of memory cells passing verify for the i^{th} data state (Pᵢ) of the subset of Y data states is less than the respective first threshold for the i^{th} data state (T₁ᵢ). In response to the determined number of memory cells passing verify for the i^{th} data state (Pᵢ) being less than the respective first threshold for the i^{th} data state (T₁ᵢ) at 1245, a value of its respective gate-to-body voltage difference might be increased at 1247. As discussed with reference to FIG. 6, this might be achieved by increasing the programming voltage level Vpgm and maintaining a channel voltage level (e.g., maintaining its corresponding voltage level 560ᵢ), increasing the programming voltage level Vpgm and decreasing the channel voltage level (e.g., increasing its corresponding voltage level 560ᵢ), maintaining the programming voltage level Vpgm and decreasing the channel voltage level (e.g., increasing its corresponding voltage level 560ᵢ), increasing the programming voltage level Vpgm and increasing the channel voltage level by a magnitude less than the magnitude of the increase of the programming voltage level Vpgm, or decreasing the programming voltage level Vpgm and decreasing the channel voltage level by a magnitude greater than the magnitude of the decrease of the programming voltage level Vpgm. The process might then proceed to 1255. If the determined number of memory cells passing verify for the i^{th} data state (Pᵢ) is greater than or equal to the respective first threshold for the i^{th} data state (T₁ᵢ) at 1245, the process might proceed to 1249.

At 1249, it might be determined whether the determined number of memory cells passing verify for the i^{th} data state (Pᵢ) of the subset of Y data states is greater than the respective second threshold for the i^{th} data state (T₂ᵢ). In response to the determined number of memory cells passing verify for the i^{th} data state (Pᵢ) being greater than the respective second threshold for the i^{th} data state (T₂ᵢ) at 1249, a value of its respective gate-to-body voltage difference might be decreased at 1251. As discussed with reference to FIG. 6, this might be achieved by decreasing the programming voltage level Vpgm and maintaining a channel voltage level, decreasing the programming voltage level Vpgm and increasing the channel voltage level, maintaining the programming voltage level Vpgm and increasing the channel voltage level, decreasing the programming voltage level Vpgm and decreasing the channel voltage level by a magnitude less than the magnitude of the decrease of the programming voltage level Vpgm, or increasing the programming voltage level Vpgm and increasing the channel voltage level by a magnitude greater than the magnitude of the increase of the programming voltage level Vpgm. The process might then proceed to 1255. In response to the determined number of memory cells passing verify for the i^{th} data state (Pᵢ) being less than or equal to the respective second threshold for the i^{th} data state (T₂ᵢ) at 1249, the process might proceed to 1253.

At 1253, with the determined number of memory cells passing verify for the i^{th} data state (Pᵢ) being greater than or equal to the respective first threshold for the i^{th} data state (T₁ᵢ) and less than or equal to the respective second threshold for the i^{th} data state (T₂ᵢ), a value of its respective gate-to-body voltage difference might be maintained. This might be achieved by maintaining the programming voltage level Vpgm and maintaining the channel voltage level, decreasing the programming voltage level Vpgm and decreasing the channel voltage level by a magnitude equal to the magnitude of the decrease of the programming voltage level Vpgm, or increasing the programming voltage level Vpgm and increasing the channel voltage level by a magnitude equal to the magnitude of the increase of the programming voltage level Vpgm. The process might then proceed to 1255.

At 1255, the value of i might be incremented by 1 (e.g., a step increase of 1) and the process might return to 1243 to repeat the process of 1243-1251 for each remaining value of i that is less than or equal to Y.

In response to i being greater than Y at 1243, the process might return to 1009 of FIG. 10 to perform the subsequent programming operation using the selectively modified values of the channel voltage levels of the plurality of channel voltage levels resulting from the selective modification of the gate-to-body voltage differences.

Although the embodiment of FIG. 12B only looked to two threshold values for each data state, it could equally apply to embodiments utilizing more than two threshold values in a manner similar to that discussed with reference to FIG. 12A.

Although the flowchart of FIG. 12B depicts the consideration of individual data states to occur sequentially in a particular order, these acts could be performed in a different order, or they could be performed concurrently for two or more, including up to all, of the data states of the subset of Y data states. In addition, while the number of memory cells passing verify for a data state is evaluated sequentially against its respective first and second thresholds in a particular order, this order could be altered, or the evaluations could be performed concurrently.

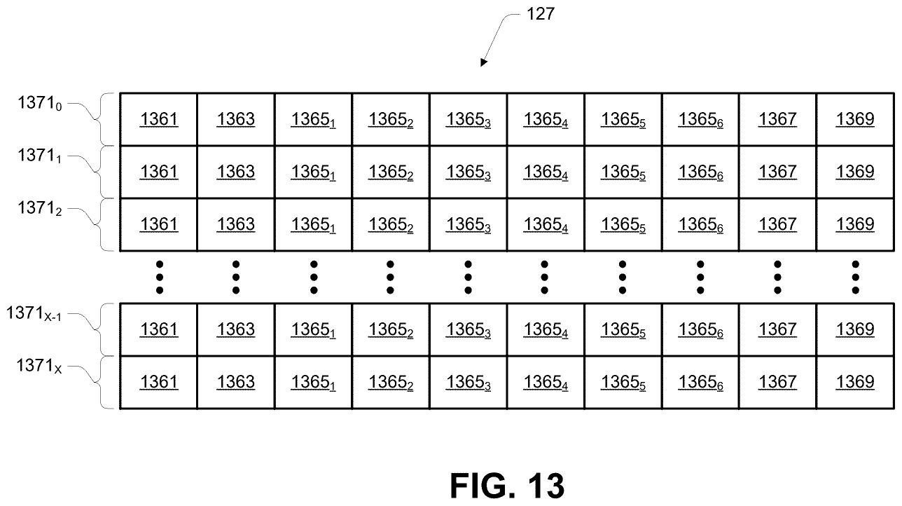

FIG. 13 is a conceptual depiction of a portion of a trim register 127 as could be used with embodiments. The example of FIG. 13 might depict trim value registers for use with a programming operation such as described with reference to FIG. 5. In the example of FIG. 13, the trim register 127 might contain a number of trim value registers, e.g., trim value registers 1361, 1363, 1365₁-1365₆, 1367, and 1369, in each register set 1371₀-1371_{X}. Each register set 1371 might correspond to a respective grouping of memory cells containing one or more logical pages of memory cells, which can include logical pages of memory cell of one or more blocks of memory cells. The trim value register 1361 of a register set 1371 might be configured to store a value indicative of an address or range of addresses of its respective grouping of memory cells. The trim value register 1363 of a register set 1371 might be configured to store a value indicative of the voltage level 560₀ of a programming pulse 562 for its respective grouping of memory cells. For some embodiments, the trim value register 1363 might be eliminated, e.g., where the voltage level 560₀ is constant for all programming operations or where its value is otherwise predefined. The trim value registers 1365₁-1365₆ of a register set 1371 might be configured to store respective values indicative of the voltage levels 560₁-560₆, respectively, of a programming pulse 562 for its respective grouping of memory cells. The trim value register 1367 of a register set 1371 might be configured to store a value indicative of the pass voltage level Vpass of a programming pulse 562 for its respective grouping of memory cells. For some embodiments, the trim value register 1367 might be eliminated, e.g., where the pass voltage level Vpass is constant for all programming operations or where its value is otherwise predefined. The trim value register 1369 of a register set 1371 might be configured to store a value indicative of the programming voltage level Vpgm of a programming pulse 562, e.g., an initial programming pulse 562 of a programming operation, for its respective grouping of memory cells. For some embodiments, the trim value register 1369 might be eliminated, e.g., where the programming voltage level Vpgm is constant for the initial programming pulse of all programming operations or where its value is otherwise predefined.

Although the portion of the trim register 127 in FIG. 13 is depicted to contain a contiguous grouping of trim value registers, such is not required. Initial values of the trim value registers 1361-1369 for each register set 1371 might be populated by a fabricator of the memory during testing or validation. Methods of various embodiments might be used to update the values of the trim value registers 1365₁-1365₆ for an individual grouping of memory cells by performing a programming operation on a representative logical page of memory cells of the grouping of memory cells, and selectively modifying the values of the trim value registers 1365₁-1365₆ of the corresponding register set 1371 indicative of the voltage levels 560₁-560₆ to be used for a subsequent programming operation within its corresponding grouping of memory cells. Method of various embodiments might further be used to update the value of the trim value register 1369 for an individual grouping of memory cells. The methods of various embodiments might be performed in response to a command from an external device, e.g., a processor 130, or they might be performed periodically by the memory, e.g., autonomously in response to a timer or other quantitative indicator, such as a number of program/erase cycles performed on each grouping of memory cells or its representative logical page of memory cells.

Following application of a programming pulse in accordance with embodiments, the memory cells might be further programmed to their desired data states from their respective interim threshold voltage distributions 730. For example, L1 memory cells of the interim threshold voltage distribution 730₁ might be further programmed to shift their threshold voltages to fall within the threshold voltage distribution 330₁ corresponding to their desired data state, L2 memory cells of the interim threshold voltage distribution 730₂ might be further programmed to shift their threshold voltages to fall within the threshold voltage distribution 330₂ corresponding to their desired data state, L3 memory cells of the interim threshold voltage distribution 730₃ might be further programmed to shift their threshold voltages to fall within the threshold voltage distribution 330₃ corresponding to their desired data state, L4 memory cells of the interim threshold voltage distribution 730₄ might be further programmed to shift their threshold voltages to fall within the threshold voltage distribution 330₄ corresponding to their desired data state, L5 memory cells of the interim threshold voltage distribution 730₅ might be further programmed to shift their threshold voltages to fall within the threshold voltage distribution 330s corresponding to their desired data state, L6 memory cells of the interim threshold voltage distribution 730₆ might be further programmed to shift their threshold voltages to fall within the threshold voltage distribution 330₆ corresponding to their desired data state, and L7 memory cells of the interim threshold voltage distribution 730₇ might be further programmed to shift their threshold voltages to fall within the threshold voltage distribution 330₇ corresponding to their desired data state. This further programming might utilize a different programming technique from the programming pulse, such as ISPP, although other known programming techniques might alternatively be used to complete the programming, e.g., shifting threshold voltages of all selected memory cells of the programming operation to their corresponding desired range of threshold voltages.

### CONCLUSION

Although specific embodiments have been illustrated and described herein, it will be appreciated by those of ordinary skill in the art that any arrangement that is calculated to achieve the same purpose might be substituted for the specific embodiments shown. Many adaptations of the embodiments will be apparent to those of ordinary skill in the art. Accordingly, this application is intended to cover any adaptations or variations of the embodiments.

What is claimed is:

1. A memory, comprising:
an array of memory cells comprising a plurality of strings of series-connected memory cells;
a plurality of access lines, wherein each access line of the plurality of access lines is connected to a control gate of a respective memory cell of each string of series-connected memory cells of the plurality of strings of series-connected memory cells; and
a controller for access of the array of memory cells, wherein the controller is configured to cause the memory to:
develop a respective channel voltage level of a plurality of channel voltage levels in a channel of each memory cell of a plurality of memory cells selected for a programming operation, wherein each memory cell of the plurality of memory cells is connected to a selected access line of the plurality of access lines for the programming operation, wherein each memory cell of the plurality of memory cells has a respective desired data state of a plurality of possible data states for the programming operation, and wherein each channel voltage level of the plurality of channel voltage levels correspond to a respective data state of the plurality of possible data states;
apply a programming voltage level to the selected access line;
determine a number of memory cells of the plurality of memory cells passing verify for each data state of a subset of Y data states of the plurality of possible data states, wherein Y is an integer value greater than or equal to one and less than or equal to a number of data states of the plurality of possible data states minus two;
for each data state of the subset of Y data states, selectively modify a value of the respective channel voltage level of the plurality of channel voltage levels for that data state in response to at least the determined number of memory cells passing verify for that data state; and
perform a subsequent programming operation using the selectively modified values of the channel voltage levels of the plurality of channel voltage levels.

2. The memory of claim 1, wherein the controller being configured to cause the memory to selectively modify values of the channel voltage levels for each data state of the subset of Y data states comprises the controller being configured to cause the memory to:
for i=1 to Y step 1:
in response to the number of memory cells passing verify for an i^{th} data state of the subset of Y data states being less than a respective first threshold, decrease the value of the respective channel voltage level for the i^{th} data state; and
in response to the number of memory cells passing verify for the i^{th} data state being greater than a respective second threshold, increase the value of the respective channel voltage level for the i^{th} data state.

3. The memory of claim 1, wherein the controller is further configured to cause the memory to:
determine a number of memory cells of the plurality of memory cells passing verify for each data state of a subset of Z data states of the plurality of possible data states, wherein Z is an integer value greater than Y and less than or equal to the number of data states of the plurality of possible data states minus one;
selectively modify a value of the programming voltage level in response to the determined total number of memory cells of the plurality of memory cells passing verify for each data state of the subset of Z data states; and
perform the subsequent programming operation using the selectively modified value of the programming voltage level.

4. The memory of claim 3, wherein the controller being configured to cause the memory to selectively modify values of the channel voltage levels for each data state of the subset of Y data states comprises the controller being configured to cause the memory to:
for i=1 to Y step 1:
in response to the number of memory cells passing verify for an i^{th} data state of the subset of Y data states being less than a respective first threshold, increase a value of gate-to-body voltage difference for the i^{th} data state;
in response to the number of memory cells passing verify for the i^{th} data state being greater than a respective second threshold, decrease the value of the gate-to-body voltage difference for the i^{th} data state; and
in response to the number of memory cells passing verify for the i^{th} data state being greater than or equal to its respective first threshold and being less than or equal to its respective second threshold, maintain the value of the gate-to-body voltage difference for the i^{th} data state.

5. The memory of claim 4, wherein the controller being configured to cause the memory to increase the value of gate-to-body voltage difference for the i^{th} data state comprises the controller being configured to cause the memory to perform an act selected from a group consisting of increase the programming voltage level and maintain the respective channel voltage level for the i^{th} data state, increase the programming voltage level and decrease the respective channel voltage level for the i^{th} data state, maintain the programming voltage level and decrease the respective channel voltage level for the i^{th} data state, increase the programming voltage level and increase the respective channel voltage level for the i^{th} data state by a magnitude less than a magnitude of the increase of the programming voltage level, and decrease the programming voltage level and decrease the respective channel voltage level for the i^{th} data state by a magnitude greater than a magnitude of the decrease of the programming voltage level.

6. The memory of claim 4, wherein the controller being configured to cause the memory to decrease the value of gate-to-body voltage difference for the i^{th} data state comprises the controller being configured to cause the memory to perform an act selected from a group consisting of decrease the programming voltage level and maintain the respective channel voltage level for the i^{th} data state, decrease the programming voltage level and increase the respective channel voltage level for the i^{th} data state, maintain the programming voltage level and increase the respective channel voltage level for the i^{th} data state, decrease the programming voltage level and decrease the respective channel voltage level for the i^{th} data state by a magnitude less than a magnitude of the decrease of the programming voltage level, and increase the programming voltage level and increase the respective channel voltage level for the i^{th} data state by a magnitude greater than a magnitude of the increase of the programming voltage level.

7. The memory of claim 4, wherein the controller is further configured to cause the memory to:
for i=1 to Y step 1:
in response to the number of memory cells passing verify for the i^{th} data state of the subset of Y data states being less than the respective first threshold and greater than or equal to a respective third threshold, increase the value of gate-to-body voltage difference for the i^{th} data state by a respective first magnitude;
in response to the number of memory cells passing verify for an i^{th} data state of the subset of Y data states being less than the respective third threshold, increase the value of gate-to-body voltage difference for the i^{th} data state by a respective second magnitude greater than the respective first magnitude;
in response to the number of memory cells passing verify for the i^{th} data state being greater than the respective second threshold and less than or equal to a respective fourth threshold, decrease the value of the gate-to-body voltage difference for the i^{th} data state by a respective third magnitude; and
in response to the number of memory cells passing verify for the i^{th} data state being greater than the respective fourth threshold, decrease the value of the gate-to-body voltage difference for the i^{th} data state by a respective fourth magnitude greater than the respective third magnitude.

8. The memory of claim 4, wherein the controller is further configured to cause the memory to:
for i=1 to Y step 1:
in response to the number of memory cells passing verify for the i^{th} data state of the subset of Y data states being less than the respective first threshold, increase the value of gate-to-body voltage difference for the i^{th} data state by a respective first magnitude determined in response to the number of memory cells passing verify for the i^{th} data state; and
in response to the number of memory cells passing verify for the i^{th} data state being greater than the respective second threshold, decrease the value of the gate-to-body voltage difference for the i^{th} data state by a respective third magnitude determined in response to the number of memory cells passing verify for the i^{th} data state.

9. A memory, comprising:
an array of memory cells comprising a plurality of strings of series-connected memory cells;
a plurality of access lines, wherein each access line of the plurality of access lines is connected to a control gate of a respective memory cell of each string of series-connected memory cells of the plurality of strings of series-connected memory cells; and
a controller for access of the array of memory cells, wherein the controller is configured to cause the memory to:
develop a first channel voltage level of a plurality of channel voltage levels in a channel of each memory cell of a plurality of memory cells selected for a programming operation and having a highest data state of a plurality of possible data states of the programming operation, wherein each memory cell of the plurality of memory cells is connected to a selected access line of the plurality of access lines for the programming operation;
for i=2 to D step 1, where D is an integer value equal to a number of data states of the plurality of possible data states:
develop an i^{th} channel voltage level of the plurality of channel voltage levels in a channel of each memory cell of the plurality of memory cells selected for the programming operation and having an i^{th} data state of the plurality of possible data states, wherein the i^{th} channel voltage level is higher than an (i-1)th channel voltage level;
apply a programming voltage level to the selected access line while each memory cell of the plurality of memory cells has its respective channel voltage level;
determine a number of memory cells of the plurality of memory cells passing verify for each data state of the plurality of possible data states other than the highest data state and a lowest data state of the plurality of possible data states;
for each data state of the plurality of possible data states other than the highest data state and the lowest data state, selectively modify a value of the respective channel voltage level of the plurality of channel voltage levels for that data state in response to the determined number of memory cells passing verify for that data state; and
perform a subsequent programming operation using the selectively modified values of the channel voltage levels of the plurality of channel voltage levels.

10. The memory of claim 9, wherein each channel voltage level of the plurality of channel voltage levels corresponds to a respective data state of the plurality of data states, and wherein the respective data state of the plurality of data states for one channel voltage level of the plurality of channel voltage levels is higher than the respective data state of the plurality of data states for each channel voltage level of the plurality of channel voltage levels that is higher than the one channel voltage level, and is lower than the respective data state of the plurality of data states for each channel voltage level of the plurality of channel voltage levels that is lower than the one channel voltage level.

11. The memory of claim 9, wherein the controller is further configured to cause the memory to:
determine a number of memory cells of the plurality of memory cells passing verify for the highest data state;
selectively modify a value of the programming voltage level in response to at least the determined number of memory cells of the plurality of memory cells passing verify for each data state of the plurality of possible data states other than the lowest data state; and
perform the subsequent programming operation using the selectively modified value of the programming voltage level.

12. The memory of claim 11, wherein the controller is further configured to cause the memory to determine a number of memory cells of the plurality of memory cells passing verify for the lowest data state, and wherein the controller being configured to cause the memory to selectively modify the value of the programming voltage level in response to at least the determined number of memory cells of the plurality of memory cells passing verify for each data state of the plurality of possible data states other than the lowest data state comprises the controller being configured to cause the memory to selectively modify the value of the programming voltage level in response to the determined number of memory cells of the plurality of memory cells passing verify for each data state of the plurality of possible data states.

13. The memory of claim 11, wherein the controller being configured to cause the memory to selectively modify values of the channel voltage levels for each data state of the plurality of possible data states other than the highest data state and the lowest data state comprises the controller being configured to cause the memory to:
for i=2 to D−1 step 1:
in response to the number of memory cells passing verify for the i^{th} data state of the plurality of possible data states being less than a respective first threshold, increase a value of gate-to-body voltage difference for the i^{th} data state;
in response to the number of memory cells passing verify for the i^{th} data state being greater than a respective second threshold, decrease the value of the gate-to-body voltage difference for the i^{th} data state; and
in response to the number of memory cells passing verify for the i^{th} data state being greater than or equal to its respective first threshold and being less than or equal to its respective second threshold, maintain the value of the gate-to-body voltage difference for the i^{th} data state.

14. The memory of claim 13, wherein the respective first threshold for one data state of the plurality of data states is equal to the respective first threshold for at least one other data state of the plurality of data states, and wherein the respective second threshold for the one data state of the plurality of data states is equal to the respective second threshold for at least one other data state of the plurality of data states.

15. The memory of claim 13, wherein, for each data state of the plurality of possible data states other than the highest data state and the lowest data state, the respective second threshold for that data state is greater than or equal to the respective first threshold for that data state.

16. A memory, comprising:
an array of memory cells comprising a plurality of strings of series-connected memory cells;
a plurality of access lines, wherein each access line of the plurality of access lines is connected to a control gate of a respective memory cell of each string of series-connected memory cells of the plurality of strings of series-connected memory cells; and
a controller for access of the array of memory cells, wherein the controller is configured to cause the memory to:
develop a respective channel voltage level of a plurality of channel voltage levels in a channel of each memory cell of a plurality of memory cells selected for a programming operation, wherein each memory cell of the plurality of memory cells is connected to a selected access line of the plurality of access lines for the programming operation, wherein each memory cell of the plurality of memory cells has a respective desired data state of a plurality of possible data states for the programming operation, and wherein each channel voltage level of the plurality of channel voltage levels correspond to a respective data state of the plurality of possible data states;
apply a programming pulse having a programming voltage level to the selected
determine a number of memory cells of the plurality of memory cells passing verify for each data state of a subset of Z data states of the plurality of possible data states, wherein Z is an integer value greater than Y and less than or equal to a number (D) of data states of the plurality of possible data states, and wherein Y is an integer value greater than or equal to one and less than or equal to D−2;
selectively modify a value of the programming voltage level in response to the determined total number of memory cells of the plurality of memory cells passing verify for each data state of the subset of Z data states;
for each data state of a subset of Y data states, selectively modify a value of the respective channel voltage level of the plurality of channel voltage levels for that data state in response to at least the determined number of memory cells passing verify for that data state and the selectively modified value of the programming voltage level, wherein the subset of Y data states is devoid of at least a lowest data state of the plurality of possible data states and a highest data state of the plurality of possible data states; and
perform a subsequent programming operation using the selectively modified values of the channel voltage levels of the plurality of channel voltage levels and using the selectively modified value of the programming voltage level.

17. The memory of claim 16, wherein the subset of Y data states includes each data state of the plurality of possible data states other than the lowest data state and the highest data state, and wherein the subset of Z data states includes each data state of the plurality of possible data states higher than the lowest data state.

18. The memory of claim 16, wherein the subset of Z data states further includes the lowest data state.

19. The memory of claim 16, wherein the controller being configured to cause the memory to selectively modify the value of the respective channel voltage level for one data state comprises the controller being configured to cause the memory to selectively modify a value of a voltage level of the programming pulse corresponding to the one data state.

20. The memory of claim 16, wherein the controller being configured to cause the memory to selectively modify the value of the respective channel voltage level for the one data state further comprises the controller being configured to cause the memory to decrease the value of the voltage level of the programming pulse corresponding to the one data state in response to a desire to increase the respective channel voltage level for the one data state, and to cause the memory to increase the value of the voltage level of the programming pulse corresponding to the one data state in response to a desire to decrease the respective channel voltage level for the one data state.
